(19) United States
(12) Patent Application Publication
(10) Pub. No.: US 2025/0142811 A1
(43) Pub. Date: May 1, 2025

(54) SEMICONDUCTOR MEMORY DEVICE AND METHOD FOR MANUFACTURING THE SAME

(71) Applicant: Samsung Electronics Co., Ltd., Suwon-si (KR)

(72) Inventors: Hyojin PARK, Suwon-si (KR); Jinbum KIM, Suwon-si (KR); Sung-Hwan JANG, Suwon-si (KR); Dae-Jin NAM, Suwon-si (KR); Sunguk JANG, Suwon-si (KR)

(73) Assignee: Samsung Electronics Co., Ltd., Suwon-si (KR)

(21) Appl. No.: 18/890,123

(22) Filed: Sep. 19, 2024

(30) Foreign Application Priority Data
Nov. 1, 2023 (KR) 10-2023-0149045

(51) Int. Cl. H10B 12/00

(52) U.S. Cl. CPC H10B 12/482; H10B 12/315; H10B 12/488; H10B 12/50

(57) ABSTRACT

A semiconductor memory device may include bit lines spaced apart from each other in a first direction on a substrate and extending in a second direction, a first active pattern and a second active pattern on the bit lines and are spaced apart from each other in the second direction, and first and second word lines between the first active and second active patterns. The first and second word lines respectively may be adjacent to the first and second active patterns. The first active pattern and/or the second active pattern may include a body portion extending in a third direction and a protruding portion protruding from an upper end of the body portion in the third direction. The protruding portion may have a width in the second direction that is greater than that of the body portion. The third direction may differ from the first and second directions.

### CROSS-REFERENCE TO RELATED APPLICATION

This application claims priority to and the benefit of Korean Patent Application No. 10-2023-0149045 filed at the Korean Intellectual Property Office on Nov. 1, 2023, the entire contents of which are incorporated herein by reference.

### BACKGROUND

### (a) Field

The present disclosure relates to a semiconductor memory device and a manufacturing method thereof, and more particularly, to a semiconductor memory device including a vertical channel transistor (VCT) and a method for manufacturing (fabricating) the same.

### (b) Description of the Related Art

There is a need to increase a degree of integration of a semiconductor memory device to meet excellent performance and low price required by a consumer. Because the degree of integration of the semiconductor memory device is an important factor in determining a price of a product, the increased degree of integration is particularly required.

Because a degree of integration of a two-dimensional or planar semiconductor memory device is mainly determined by an area occupied by a unit memory cell, the degree of integration of the two-dimensional or planar semiconductor memory device is greatly influenced by a level of fine pattern formation technology. However, because ultra-expensive equipment is required to refine the pattern, the degree of integration of the two-dimensional semiconductor memory device is increasing but still limited. Accordingly, a semiconductor memory device including a vertical channel transistor in which a channel extends in a vertical direction is being proposed.

### SUMMARY

One aspect of the present disclosure is to provide a semiconductor memory device and a method for manufacturing the same in which a contact resistance may decrease by increasing a contact area between an active pattern and a contact pattern so that a time taken to read data is shortened by improving a current (or an electric current) and a misalignment between the active pattern and the contact pattern may be improved.

According to an example embodiment, a semiconductor memory device may include a substrate; bit lines above the substrate and spaced apart from each other in a first direction, the bit lines extending in a second direction, the second direction being different from the first direction; a first active pattern and a second active pattern on the bit lines and spaced apart from each other in the second direction; and a first word line and a second word line between the first active pattern and the second active pattern, the first word line being adjacent to the first active pattern and the second word line being adjacent to the second active pattern. The first active pattern, the second active pattern, or both the first active pattern and the second active pattern may include a body portion and a protruding portion. The body portion may extend in a third direction. The protruding portion may protrude from an upper end of the body portion in the third direction and may have a width in the second direction that is greater than a width of the body portion in the second direction. The third direction may be different from the first direction and the second direction.

According to an example embodiment, a semiconductor memory device may include a substrate; bit lines above the substrate and spaced apart from each other in a first direction, the bit lines extending in a second direction, the second direction being different from the first direction; a first active pattern and a second active pattern on the bit lines and spaced apart from each other in the second direction; and a first word line and a second word line between the first active pattern and the second active pattern, the first word line being adjacent to the first active pattern and the second word line being adjacent to the second active pattern. The first active pattern, the second active pattern, or both the first active pattern and the second active pattern may include a body portion and a protruding portion. The body portion may extend in a third direction. The protruding portion may protrude from an upper end of the body portion in the third direction. The protruding portion may include a central portion and a surface layer portion surrounding the central portion. The central portion may include a monocrystalline semiconductor material that is not doped with an impurity. The surface layer portion may include a monocrystalline semiconductor material that is doped with an impurity.

According to an example embodiment, a semiconductor memory device may include a substrate; bit lines above the substrate and spaced apart from each other in a first direction, the bit lines extending in a second direction, the second direction being different from the first direction; a first active pattern and a second active pattern on the bit lines and spaced apart from each other in the second direction; a first word line and a second word line between the first active pattern and the second active pattern, the first word line being adjacent to the first active pattern and the second word line being adjacent to the second active pattern; a first back gate electrode facing the first word line with the first active pattern between the first word line and the first back gate electrode; and a second back gate electrode facing the second word line with the second active pattern between the second word line and the second back gate electrode. The first active pattern, the second active pattern, or both the first active pattern and the second active pattern may include a body portion and a protruding portion. The body portion may extend in a third direction. The protruding portion may protrude from an upper end of the body portion in the third direction and may have a width along the second direction that may be greater than a width of the body portion. The protruding portion may include a central portion and a surface layer portion surrounding the central portion. The central portion may include a monocrystalline semiconductor material that is not doped with an impurity, and the surface layer portion may include a monocrystalline semiconductor material doped with an impurity.

In the semiconductor memory device and the method for manufacturing the same according to embodiments, a contact resistance may decrease by increasing a contact area between an active pattern and a contact pattern so that a time taken to read data is shortened by improving a current (or an electric current), and a misalignment between the active pattern and the contact pattern may be improved.

### BRIEF DESCRIPTION OF THE DRAWINGS

FIG. 1 is a schematic layout diagram of a semiconductor memory device according to an embodiment.

FIG. 2 is a plan view of a cell array region of FIG. 1.

FIG. 3 is a cross-sectional view cut along lines A-A and B-B of FIG. 2.

FIG. 4 is a cross-sectional view cut along lines C-C and D-D of FIG. 2.

FIG. 5 is an enlarged cross-sectional view of a portion P of FIG. 3.

FIG. 6 is an enlarged cross-sectional view of a portion Q of FIG. 4.

FIGS. 7 to 11 are views for describing the semiconductor memory device according to some embodiments, and are views corresponding to FIG. 5.

FIGS. 12 to 54 are views for describing a method for manufacturing the semiconductor memory device according to an embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In addition, throughout the specification, two directions parallel to an upper surface of a substrate and intersecting each other are defined as a first direction D1 and a second direction D2 and a direction perpendicular to the upper surface of the substrate is defined as a third direction D3. For example, the first direction D1 and the second direction D2 may be perpendicular to each other.

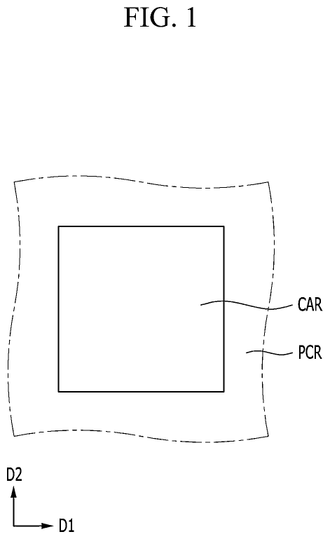

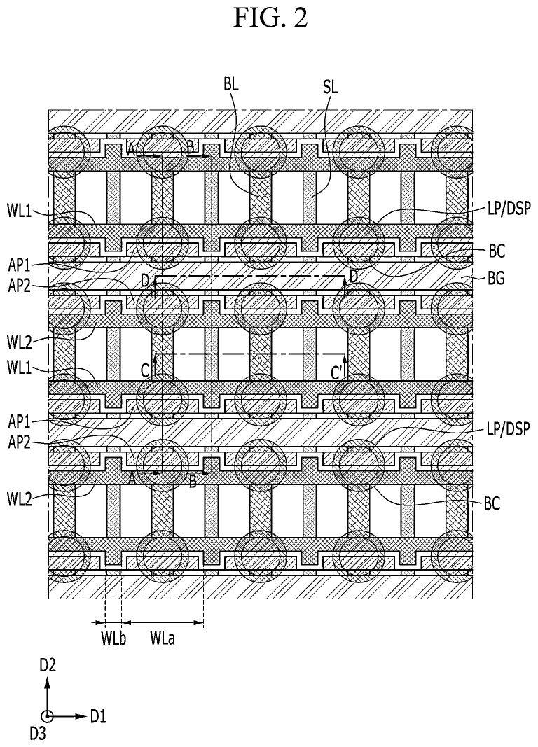

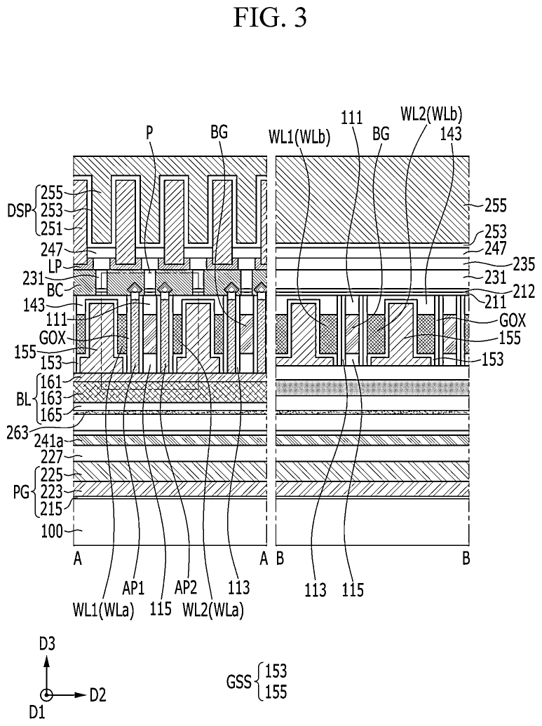

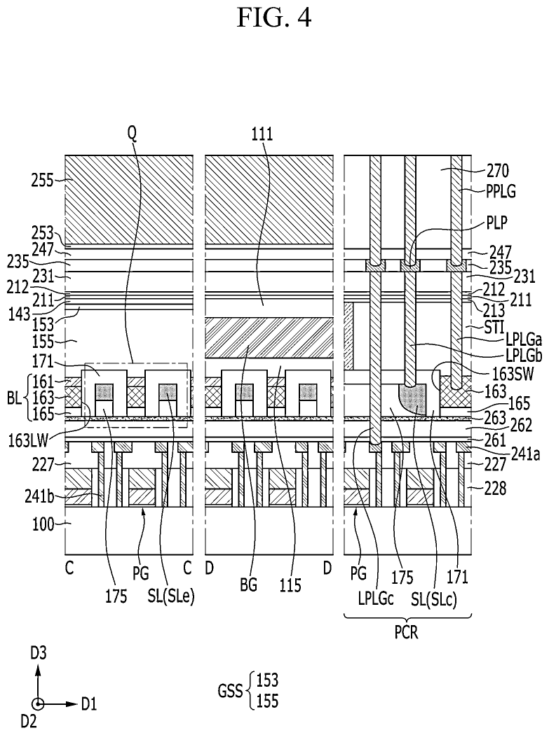

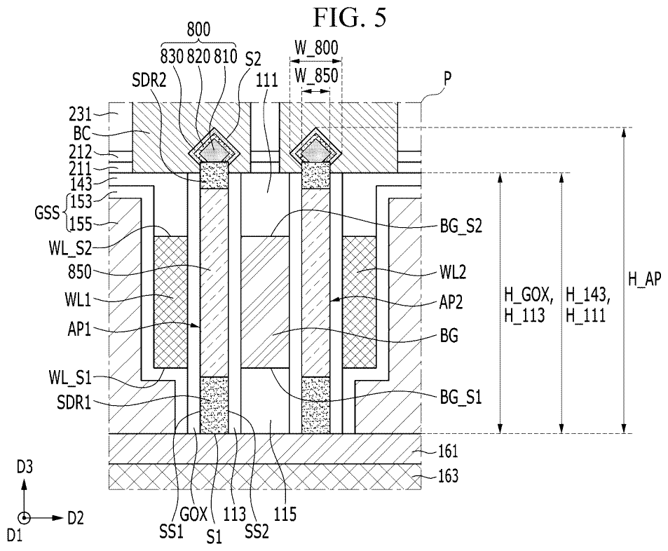

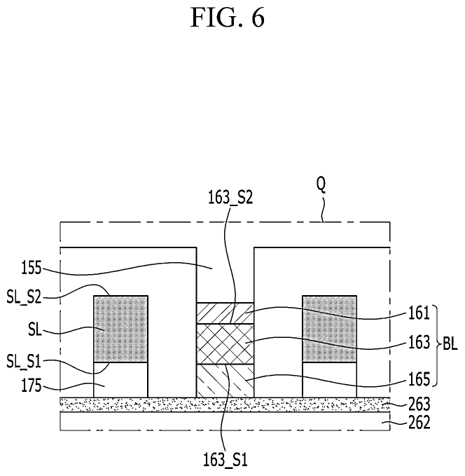

FIG. 1 is a schematic layout diagram of a semiconductor memory device according to an embodiment. FIG. 2 is a plan view of a cell array region of FIG. 1. FIG. 3 is a cross-sectional view cut along lines A-A and B-B of FIG. 2. FIG. 4 is a cross-sectional view cut along lines C-C and D-D of FIG. 2. FIG. 5 is an enlarged cross-sectional view of a portion P of FIG. 3. FIG. 6 is an enlarged cross-sectional view of a portion Q of FIG. 4. For reference, FIG. 4 includes a cross-sectional view of a peripheral circuit region bordering the cell array region of FIG. 1.

The semiconductor memory device according to some embodiments may include a memory cell that includes a vertical channel transistor (VCT).

Referring to FIGS. 1 to 6, the semiconductor memory device according to the some embodiments includes a substrate 100, a bit line BL, a first word line WL1, a second word line WL2, a back gate electrode BG, a first active pattern AP1, a second active pattern AP2, and a contact pattern BC.

The substrate 100 may include a cell array region CAR and a peripheral circuit region PCR. Memory cells may be disposed above or on the substrate 100 of the cell array region CAR.

The substrate 100 may be a silicon substrate, or may include another material (for example, silicon germanium, indium antimonide, a lead tellurium compound, indium arsenide, indium phosphide, gallium arsenide, or gallium antimonide, but the present disclosure is not limited thereto.

Selectively, a peripheral gate structure PG may be disposed on the substrate 100. The peripheral gate structure PG may be disposed across the cell array region CAR and the peripheral circuit region PCR. In other words, a portion of the peripheral gate structure PG may be disposed at the cell array region CAR of the substrate 100, and the remainder of the peripheral gate structure PG may be disposed at the peripheral circuit region PCR of the substrate 100.

The peripheral gate structure PG may be included in a sensing transistor, a transmission transistor, a driving transistor, and the like. For example, the peripheral gate structure PG included in the sensing transistor may be disposed on the substrate 100 of the cell array region CAR, but the present disclosure is not limited thereto. A type of a transistor of a peripheral circuit disposed above or on the substrate 100 of the cell array region CAR may vary depending on design disposition of the semiconductor memory device.

The peripheral gate structure PG may include a peripheral gate insulating film 215, a peripheral gate conduction pattern 223, and a peripheral gate mask pattern 225. The peripheral gate insulating film 215 may include a silicon oxide film, a silicon oxynitride film, a high dielectric constant insulating film having a higher dielectric constant than the silicon oxide film, or a combination thereof. For example, the high dielectric constant insulating film may include metal oxide, metal oxynitride, metal silicon oxide, metal silicon oxynitride, or a combination thereof, but the present disclosure is not limited thereto. The peripheral gate conduction pattern 223 may include a conductive material, and for example, the peripheral gate conduction pattern 223 may include a doped semiconductor material, conductive metal nitride, conductive metal silicon nitride, metal carbonitride, conductive metal silicide, conductive metal oxide, a two-dimensional (2D) material, a metal, or a combination thereof. The peripheral gate mask pattern 225 is made of an insulating material. In the semiconductor memory device according to some embodiments, the two-dimensional material may be a metallic material and/or a semiconductor material. The two-dimensional material may include a two-dimensional allotrope or a two-dimensional compound, and for example, the two-dimensional material may include graphene, molybdenum sulfide (MoS₂), molybdenum diselenide (MoSe₂), tungsten diselenide (WSe₂), tungsten sulfide (WS₂), or a combination thereof, but the present disclosure is not limited thereto. In other words, because the above-described two-dimensional material is listed only as an example, the two-dimensional material that may be included in the semiconductor memory device of the present disclosure is not limited by the above-described material.

A first peri lower insulating film (or a first peripheral lower insulating film) 227 and a second peri lower insulating film (or a second peripheral lower insulating film) 228 are disposed above or on the substrate 100. Each of the first peri lower insulating film 227 and the second peri lower insulating film 228 may be made of an insulating material.

A peri wiring line (or a peripheral wire line) 241a and a peri contact plug (or a peripheral contact plug) 241b may be disposed at the first peri lower insulating film 227 and the second peri lower insulating film 228. Although the peri wiring line 241a and the peri contact plug 241b are shown as different films, the present disclosure is not limited thereto. A boundary between the peri wiring line 241a and the peri contact plug 241b may not be distinguished. Each of the peri wiring line 241a and the peri contact plug 241b includes a conductive material.

A first peri upper insulating film (or a first peripheral upper insulating film) 261 and a second peri upper insulating film (or a second peri upper insulating film) 262 may be disposed above or on the peri wiring line 241a and the peri contact plug 241b. Each of the first peri upper insulating film 261 and the second peri upper insulating film 262 may be made of an insulating material. Unlike the drawings, a peri upper insulating film formed of a single film may be disposed above or on the peri wiring line 241a and the peri contact plug 241b.

A bonding insulating film 263 is disposed on the second peri upper insulating film 262. The bonding insulating film 263 may be used to bond a wafer. For example, the bonding insulating film 263 may include silicon carbonitride (SiCN).

Bit lines BL are disposed above the substrate. For example, the bit lines BL may be disposed above the peripheral gate structure PG, and the bit lines BL may be disposed on the bonding insulating film 263.

The bit line BL may extend long in the second direction D2. Adjacent bit lines BL may be spaced apart in the first direction D1. The bit line BL includes a long sidewall 163LW extending in the second direction D2 and a short sidewall 163SW extending in the first direction D1.

Each bit line BL may extend from the cell array region CAR to the peripheral circuit region PCR. An end portion of each bit line BL may be disposed on the peripheral circuit region PCR. A portion of the bit line BL may be disposed at a position that overlaps the peripheral circuit region PCR.

Each bit line BL may include a bit line mask pattern 165, a metal pattern 163, and a polysilicon pattern 161 sequentially stacked in the third direction D3. Unlike the drawings, the bit line BL may include one of the polysilicon pattern 161 and the metal pattern 163.

The bit line BL may include a conductive bit line. The conductive bit line includes a film made of a conductive material among the bit line BL. The conductive bit line may include the polysilicon pattern 161 and the metal pattern 163.

The metal pattern 163 may include a conductive material, and for example, the metal pattern 163 may include conductive metal nitride, conductive metal silicon nitride, metal carbonitride, conductive metal silicide, conductive metal oxide, a two-dimensional material, a metal, or a combination thereof. The bit line mask pattern 165 may include an insulating material such as silicon nitride, silicon oxynitride, or the like.

In FIG. 4, the polysilicon pattern 161 of the bit line BL is shown as not being disposed at the peripheral circuit region PCR, but the present disclosure is not limited thereto.

Selectively, a bit line shielding structure 171, SL, and 175 may be disposed above the peripheral gate structure PG. The bit line shielding structure 171, SL, and 175 may be disposed on the bonding insulating film 263, and may be in contact with the bonding insulating film 263.

The bit line shielding structure 171, SL, and 175 is disposed adjacent to the bit line BL. In the cell array region CAR, the bit line shielding structure 171, SL, and 175 may be disposed adjacent to the bit line BL in the first direction D1. That is, the bit line shielding structure 171, SL, and 175 is disposed between the bit lines BL adjacent in the first direction D1. The bit line shielding structure 171, SL, and 175 may extend in the second direction D2. The bit line shielding structure 171, SL, and 175 may contact the bit line BL.

The bit line shielding structure 171, SL, and 175 may include a bit line shielding conductive pattern SL and bit line shielding insulating films 171 and 175. The bit line shielding insulating films 171 and 175 may include a bit line shielding insulating liner 171 and a bit line shielding insulating capping film 175.

The bit line shielding insulating films 171 and 175 may surround a circumference of the bit line shielding conductive pattern SL. In other words, the bit line shielding conductive pattern SL may be disposed inside the bit line shielding insulating films 171 and 175.

The bit line shielding conductive pattern SL may include an extension portion SLe and a connection portion SLc. The extension portion SLe of the bit line shielding conductive pattern may extend along the long sidewall 163LW of the bit line. The extension portion SLe of the bit line shielding conductive pattern SL may extend in the second direction D2. The bit line shielding conductive pattern SL disposed between the bit lines BL adjacent in the first direction D1 may be the extension portion SLe of the bit line shielding conductive pattern SL.

The connection portion SLc of the bit line shielding conductive pattern SL may extend along the short sidewall 163SW of the bit line. The connection portion SLc of the bit line shielding conductive pattern SL may extend in the first direction D1. The connection portion SLc of the bit line shielding conductive pattern SL may connect extension portions SLe of bit line shielding conductive patterns SL adjacent in the first direction D1. The connection portion SLc of the bit line shielding conductive pattern SL is directly connected to the extension portion SLe of the bit line shielding conductive pattern SL.

The bit line shielding conductive pattern SL may extend from the cell array region CAR to the peripheral circuit region PCR. An end portion of the bit line shielding conductive pattern SL may be disposed on the peripheral circuit region PCR. The connection portion SLc of the bit line shielding conductive pattern SL may be disposed on the peripheral circuit region PCR.

The bit line shielding conductive pattern SL may include a conductive material, and for example, the bit line shielding conductive pattern SL may include at least one of conductive metal nitride, conductive metal silicon nitride, metal carbonitride, conductive metal silicide, conductive metal oxide, a two-dimensional material, and a metal.

Each of the bit line shielding insulating liner 171 and the bit line shielding insulating capping film 175 may be made of an insulating material. If the bit line shielding insulating liner 171 and the bit line shielding insulating capping film 175 include the same material, a boundary between the bit line shielding insulating liner 171 and the bit line shielding insulating capping film 175 may not be distinguished.

The bit line shielding structure 171, SL, and 175 may be disposed between the bit lines BL adjacent in the first direction D1 so that a coupling noise between the bit lines BL is reduced.

In FIG. 4 and FIG. 6, the bit line shielding conductive pattern SL may have a first surface SL_S1 and a second surface SL_S2 opposed to each other in the third direction D3. For example, the first surface SL_S1 of the bit line shielding conductive pattern SL and the second surface SL_S2 of the bit line shielding conductive pattern SL may be included in the extension portion SLe of the bit line shielding conductive pattern SL. The metal pattern 163 of the bit line BL may have a first surface 163_S1 and a second surface 163_S2 opposed to each other in the third direction D3. The first surface SL_S1 of the bit line shielding conductive pattern SL and the first surface 163_S1 of the metal pattern 163 are closer to the bonding insulating film 263 than the second surface SL_S2 of the bit line shielding conductive pattern SL and the second surface 163_S2 of the metal pattern 163. The third direction D3 may be a thickness direction of the substrate 100.

In FIG. 4 and FIG. 6, a length of the extension portion SLe of the bit line shielding conductive pattern SL in the third direction D3 based on the bonding insulating film 263 may be equal to or greater than a length of the metal pattern 163 of the bit line BL in the third direction D3 based on the bonding insulating film 263. In addition, a height of the first surface SL_S1 of the extension portion SLe of the bit line shielding conductive pattern SL based on the bonding insulating film 263 may be equal to or less than a height of the first surface 163_S1 of the metal pattern 163 of the bit line BL based on the bonding insulating film 263, and a height of the second surface SL_S2 of the extension portion SLe of the bit line shielding conductive pattern SL based on the bonding insulating film 263 may be equal to or greater than a height of the second surface 163_S2 of the metal pattern 163 of the bit line BL based on the bonding insulating film 263. That is, the extension portion SLe of the bit line shielding conductive pattern SL may extend in the third direction D3, and may extend to overlap the metal pattern 163 of the bit line BL in the first direction D1. Accordingly, the semiconductor memory device may control coupling between the bit lines BL through the bit line shielding structure 171, SL, and 175.

The first active pattern AP1 and the second active pattern AP2 may be disposed above each bit line BL. The first active pattern AP1 and the second active pattern AP2 may be alternately disposed along the second direction D2.

First active patterns AP1 may be spaced apart from each other in the first direction D1. The first active patterns AP1 may be spaced apart at regular intervals. Second active patterns AP2 may be spaced apart from each other in the first direction D1. The second active patterns AP2 may be spaced apart at regular intervals. That is, the first and second active patterns AP1 and AP2 may be two-dimensionally disposed along the first direction D1 and the second direction D2 that intersect each other.

Each of the first active pattern AP1 and the second active pattern AP2 may have a length in the first direction D1, a width in the second direction D2, and a height in the third direction D3.

The first active pattern AP1 and the second active pattern AP2 have a body portion 850 extending in the third direction D3 and a protruding portion (or a protrusion) 800 that protrudes from an upper end of the body portion 850 in the third direction D3. For example, as will be described later, the protruding portion 800 may be formed by a selective epitaxial growth (SEG) method using the body portion 850 as a seed.

Accordingly, a width W_800 of the protruding portion 800 in the second direction D2 may be larger than a width W_850 of the body portion 850 in the second direction D2. Here, for example, the width W_800 of the protruding portion 800 and the width W_850 of the body portion 850 may be the width W_800 of the protruding portion 800 in the second direction D2 and the width W_850 of the body portion 850 in the second direction D2 in FIG. 3 or FIG. 5 on a cross-section (hereinafter referred to as a first cross-section) cut in the second direction D2 and the third direction D3 at a midpoint in the first direction D1 of the first active pattern AP1 or the second active pattern AP2, respectively.

As will be described later, at least a portion of the protruding portion 800 may be disposed within the contact pattern BC, and the contact pattern BC may surround at least a portion of the protruding portion 800. Accordingly, a contact resistance may decrease by increasing a contact area between the first and second active patterns AP1 and AP2 and the contact pattern BC so that a time taken to read data is shortened by improving a current (or an electric current), and a misalignment between the first and second active patterns AP1 and AP2 and the contact pattern BC may be improved.

The body portion 850 of each of the first active pattern AP1 and the second active pattern AP2 may have a substantially uniform width W_850 in the second direction D2. That is, the body portion 850 of each of the first active pattern AP1 and the second active pattern AP2 may have substantially the same width in a first surface S1 and a second surface S2. Additionally, the width W_850 of the body portion 850 of the first active pattern AP1 along the second direction D2 may be the same as the width W_850 of the body portion 850 of the second active pattern AP2 along the second direction D2. In this time, the width W_850 of the body portion 850 along the second direction D2 may be the largest width among widths along the second direction D2 of the body portion 850, the width along the second direction D2 at the uppermost end in the third direction D3, or the width along the second direction D2 width at the lowermost end in the third direction D3.

The width W_800 of the protruding portion 800 along the second direction D2 may change along the third direction D3, and the width W_800 of the protruding portion 800 may be the largest among widths of the protruding portion 800 along the second direction D2.

For example, the width W_800 of the protruding portion 800 along the second direction D2 may gradually increase along the third direction D3, may gradually decrease along the third direction D3, or may gradually increase and then gradually decrease again along the third direction D3. Accordingly, for example, on the first cross-section, the protruding portion 800 may have a circular, elliptical, or polygonal cross-sectional shape in FIG. 3 or FIG. 5. Here, for example, the polygonal cross-sectional shape may be a triangle, a quadrangle, a pentagon, a hexagon, a rhombus, or a trapezoid.

For example, the width W_850 of the body portion 850 of each of the first active pattern AP1 and the second active pattern AP2 along the second direction D2 may be several nm to several tens of nm. For example, the width W_850 of the body portion 850 of each of the first active pattern AP1 and the second active pattern AP2 along the second direction D2 may be 1 nm to 30 nm or 1 nm to 10 nm, but the present disclosure is not limited thereto.

The width W_800 of the protruding portion 800 of each of the first active pattern AP1 and the second active pattern AP2 along the second direction D2 may be several nm to several tens of nm. For example, the width W_800 of the protruding portion 800 of each of the first active pattern AP1 and the second active pattern AP2 along the second direction D2 may be 1 nm to 30 nm or 1 nm to 10 nm, but the present disclosure is not limited thereto.

For example, the width W_800 of the protruding portion 800 along the second direction D2 may be greater than 1.0 times, 1.1 times or more, 1.2 times or more, 1.3 times or more, 1.4 times or more, 1.5 times or more. 1.6 times or more, 1.7 times or more, 1.8 times or more, 1.9 times or more, 2.0 times or more, 3.0 times or more, 4.0 times or more, 5.0 times or more, 6.0 times or more, 7.0 times or more, 8.0 times or more, 9.0 times or more, or 10.0 times or more the width W_850 of the body portion 850 along the second direction D2. For example, the width W_800 of the protruding portion 800 along the second direction D2 may be 10.0 times or less, 9.0 times or less, 8.0 times or less, 7.0 times or less, 6.0 times or less, 5.0 times or less, 4.0 times or less, 3.0 times or less, 2.0 times or less, 1.9 times or less, 1.8 times or less, 1.7 times or less, 1.6 times or less, 1.5 times or less, 1.4 times or less, 1.3 times or less, 1.2 times or less, or 1.1 times or less the width W_850 of the body portion 850 along the second direction D2.

On the other hand, a length of the body portion 850 of each of the first active pattern AP1 and the second active pattern AP2 along the first direction D1 may be larger than a line width of the bit line BL. That is, the length of the body portion 850 of each of the first active pattern AP1 and the second active pattern AP2 along the first direction D1 may be larger than a width of the bit line BL along the first direction D1.

The protruding portion 800 may extend in the first direction D1 along the body portion 850, and a length of the protruding portion 800 along the first direction D1 may be the same as the length of the body portion 850 along the first direction D1. Therefore, the length of the protruding portion 800 along the first direction D1 may be larger than the line width of the bit line BL.

For example, a length of the body portion 850 of each of the first active pattern AP1 and the second active pattern AP2 along the third direction D3 may be greater than a length of the back gate electrode BG along the third direction D3 that will be described later. For example, a height of the uppermost end of the body portion 850 of each of the first active pattern AP1 and the second active pattern AP2 along the third direction D3 based on the bit line BL may be higher than a height of a first surface BG_S1 of the back gate electrode BG based on the bit line BL.

For example, a height H_AP of the uppermost end of the protruding portion 800 of each of the first active pattern AP1 and the second active pattern AP2 along the third direction D3 based on the bit line BL may be higher than the height of the first surface BG_S1 of the back gate electrode BG based on the bit line BL.

In FIG. 5, the first active pattern AP1 and the second active pattern AP2 may have the first surface S1 and the second surface S2 facing each other in the third direction D3. Here, the first surface S1 of each of the first active pattern AP1 and the second active pattern AP2 may be a lower surface of the body portion 850, and the second surface S2 of each of the first active pattern AP1 and the second active pattern AP2 may be an upper surface of the protruding portion 800.

For example, the first surface S1 of each of the first active pattern AP1 and the second active pattern AP2 may be in contact with the polysilicon pattern 161 of the bit line BL. Unlike the drawings, if the polysilicon pattern 161 is omitted, the first surfaces S1 of the first and second active patterns AP1 and AP2 may contact the metal pattern 163.

The body portion 850 of each of the first active pattern AP1 and the second active pattern AP2 may include a first sidewall S3 and a second sidewall S4 facing each other in the second direction D2. The second sidewall S4 of the body portion 850 of the first active pattern AP1 may face the first sidewall S3 of the body portion 850 of the second active pattern AP2.

The first sidewall S3 of the body portion 850 of the first active pattern AP1 may be adjacent to a back gate electrode BG, and the second sidewall S4 of the body portion 850 of the first active pattern AP1 may be adjacent to the first word line WL1. The second sidewall S4 of the body portion 850 of the second active pattern AP2 may be adjacent to the back gate electrode BG, and the first sidewall S3 of the body portion 850 of the second active pattern AP2 may be adjacent to the second word line WL2.

For example, the body portion 850 of each of the first active pattern AP1 and the second active pattern AP2 may be made of a monocrystalline semiconductor material, and for example, the body portion 850 of each of the first active pattern AP1 and the second active pattern AP2 may be made of monocrystalline silicon.

As described above, because the protruding portion 800 is formed by a selective epitaxial growth (SEG) method using the body portion 850 as a seed, the protruding portion 800 may be made of a monocrystalline semiconductor material, and for example, the protruding portion 800 may be made of monocrystalline silicon.

For example, the protruding portion 800 may include a central portion 810 and a surface layer portion 820 surrounding the central portion 810.

As described later, the central portion 810 may be formed by performing a first selective epitaxial growth using a source gas of a semiconductor material that does not include an impurity gas, and then the surface layer portion 820 may be formed by performing a second selective epitaxial growth on a surface of the central portion 810 using a source gas of a semiconductor material that includes an impurity gas and annealing the grown epitaxial or the surface layer portion 820 may be formed by doping an impurity in the central portion 810 using gas phase diffusion (GPD) or ion implantation.

Accordingly, the central portion 810 of the protruding portion 800 may include a monocrystalline semiconductor material in which an impurity is not doped, and the surface layer portion 820 may include a monocrystalline semiconductor material in which an impurity is doped.

As an example, the monocrystalline semiconductor material may include silicon (Si), germanium (Ge), or a combination thereof.

As an example, the impurity may be an n-type impurity or a p-type impurity. The n-type impurity may include phosphorus (P), arsenic (As), antimony (Sb), or a combination thereof. If phosphorus (P) is used as the n-type impurity, phosphorus (P), phosphine (PH₃), or the like may be used as an impurity gas to dope the phosphorus (P) in a semiconductor material through gas phase doping (GPD) or ion implantation (IIP). The p-type impurity may include boron (B), aluminum (Al), gallium (Ga), indium (In), or a combination thereof. If boron (B) is used as the p-type impurity, boron (B), boron difluoride (BF₂), boron trifluoride (BF₃), or the like may be used as an impurity gas to dope the boron (B) in a semiconductor material through gas phase doping (GPD) or ion implantation (IIP).

As an example, the body portion 850 of each of the first active pattern AP1 and the second active pattern AP2 may be made of a monocrystalline semiconductor material. For example, the body portion 850 of each of the first active pattern AP1 and the second active pattern AP2 may be made of monocrystalline silicon.

As an example, the protruding portion 800 may further include an interface layer 830 surrounding the surface layer portion 820. As described later, the contact pattern BC with a metallic material may be formed on the first active pattern AP1 and the second active pattern AP2 to surround the protruding portion 800, so that the interface layer 830 including metal silicide is formed between the protruding portion 800 and the contact pattern BC. That is, the interface layer 830 may be disposed between the central portion 810 or the surface layer portion 820 of the protruding portion 800 and the contact pattern BC. The interface layer 830 of the protruding portion 800 may be disposed on the surface layer portion 820, and may surround the surface layer portion 820.

As an example, the body portion 850 of each of the first active pattern AP1 and the second active pattern AP2 may include a first dopant region SDR1 adjacent to the bit line BL and a second dopant region SDR2 adjacent to the protruding portion 800. That is, the first dopant region SDR1 may be disposed at a lower end of the body portion 850 of each of the first active pattern AP1 and the second active pattern AP2 along the third direction D3, and the second dopant region SDR2 may be disposed at an upper end of the body portion 850 of each of the first active pattern AP1 and the second active pattern AP2 along the third direction D3. The body portion 850 of each of the first active pattern AP1 and the second active pattern AP2 may include a channel region between the first dopant region SDR1 and the second dopant region SDR2.

The first dopant region SDR1 and the second dopant region SDR2 are regions doped with an impurity within the body portion 850 of each of the first active pattern AP1 and the second active pattern AP2. A concentration of the impurity within each of the first dopant region SDR1 and the second dopant region SDR2 may be greater than a concentration of an impurity of the channel region of the body portion 850 of each of the first active pattern AP1 and the second active pattern AP2.

As an example, the impurity may be an n-type impurity or a p-type impurity. The n-type impurity may include phosphorus (P), arsenic (As), antimony (Sb), or a combination thereof. The p-type impurity may include boron (B), aluminum (Al), gallium (Ga), indium (In), or a combination thereof. Because this impurity is the same as the impurity described above, a repetitive description thereof will be omitted.

As an example, the second dopant region SDR2 of the body portion 850 may be connected to the surface layer portion 820 of the protruding portion 800 including a monocrystalline semiconductor material doped with an impurity. As described later, in a process in which the central portion 810 is formed by performing a first selective epitaxial growth using a source gas of a semiconductor material that does not include an impurity gas and then the surface layer portion 820 is formed by performing a second selective epitaxial growth on a surface of the central portion 810 using a source gas of a semiconductor material that includes an impurity gas and annealing the grown epitaxial, an impurity may be doped to an upper end of the body portion 850 through the annealing to form the second dopant region SDR2 of the body portion 850. Alternatively, in a process in which the central portion 810 is formed by performing a first selective epitaxial growth using a source gas of a semiconductor material that does not include an impurity gas and then the surface layer portion 820 is formed by doping an impurity in the central portion 810 using gas phase diffusion (GPD) or ion implantation, the impurity may be doped to an upper end of the body portion 850 to form the second dopant region SDR2. Accordingly, the second dopant region SDR2 of the body portion 850 may be connected to the surface layer portion 820 of the protruding portion 800 including a monocrystalline semiconductor material doped with an impurity.

Unlike the drawings, the body portion 850 of each of the first active pattern AP1 and the second active pattern AP2 may not include at least one of the first dopant region SDR1 and the second dopant region SDR2.

During an operation of the semiconductor memory device, a channel region of each of the first active pattern AP1 and the second active pattern AP2 may be controlled by the first word line WL1, the second word line WL2, and the back gate electrode BG. Because the first active pattern AP1 and the second active pattern AP2 are made of a monocrystalline semiconductor material, a leakage current characteristic of the semiconductor memory device may be improved.

The back gate electrode BG may be disposed above the bit line BL and the bit line shielding structure 171, SL, and 175. Back gate electrodes BG may be spaced apart from each other in the second direction D2. The back gate electrodes BG may be spaced apart at regular intervals. The back gate electrode BG may extend across the bit line BL in the first direction D1.

The back gate electrode BG may be adjacent to the first sidewall S3 of the first active pattern AP1, and may be adjacent to the second sidewall S4 of the second active pattern AP2. The back gate electrode BG may be disposed outside a pair of the first active pattern AP1 and the second active pattern AP2 alternately disposed in the second direction D2. Additionally, the back gate electrode BG may be disposed between two pairs of the first active pattern AP1 and the second active pattern AP2 adjacent to each other in the second direction D2.

In other words, based on the pair of the first active patterns AP1 and the second active patterns AP2, the back gate electrode BG may be adjacent to the first sidewall S3 of the first active pattern AP1, and the back gate electrode BG may be adjacent to the second sidewall S4 of the second active pattern AP2. Additionally, the back gate electrode BG may be adjacent to the first sidewall S3 of the first active pattern AP1 belonging to one pair, and may be adjacent to the second sidewall S4 of the second active pattern AP2 belonging to another pair. That is, the back gate electrode BG may be disposed between the first active pattern AP1 belonging to the one pair and the second active pattern AP2 belonging to the other pair. The back gate electrode BG may be adjacent to the second sidewall S4 of the second active pattern AP2 belonging to one pair, and may be adjacent to the second sidewall S4 of the first active pattern AP1 belonging to another pair. That is, the back gate electrode BG may be disposed between the second active pattern AP2 belonging to the one pair and the first active pattern AP1 belonging to the other pair.

For example, the back gate electrode BG, the second active pattern AP2, the second word line WL2, a gate separation pattern (or a gate isolation pattern) GSS, the first word line WL1, the first active pattern AP1, the back gate electrode BG, the second active pattern AP2, the second word line WL2, the gate separation pattern GSS, the first word line WL1, and the first active pattern AP1 may be sequentially disposed in the second direction D2, and this disposition may be repeated in the second direction D2.

The back gate electrode BG may have the first surface BG_S1 and a second surface BG_S2 facing in the third direction D3. The first surface BG_S1 of the back gate electrode BG is closer to the bit line BL than the second surface BG_S2 of the back gate electrode BG. In other words, the first surface BG_S1 of the back gate electrode BG may be a lower end surface, and the second surface BG_S2 of the back gate electrode BG may be an upper end surface.

A length of the back gate electrode BG along the third direction D3 may be smaller than a length of each of the first active pattern AP1 and the second active pattern AP2 along the third direction D3. The length of the back gate electrode BG along the third direction D3 may be equal to or smaller than a length of each of the first word line WL1 and the second word line WL2 along the third direction D3. Additionally, a length (H_BG) of the back gate electrode BG along the third direction D3 may be equal to or smaller than a length of a word line shielding conductive pattern SS along the third direction D3 that will be described later.

The back gate electrode BG may include a conductive material, and for example, the back gate electrode BG may include doped polysilicon, conductive metal nitride, conductive metal silicon nitride, metal carbonitride, conductive metal silicide, conductive metal oxide, a two-dimensional material, a metal, or a combination thereof.

When the semiconductor memory device operates, a voltage may be applied to the back gate electrode BG, so that a threshold voltage of the vertical channel transistor may be adjusted. The leakage current characteristic may be prevented from being deteriorated by adjusting the threshold voltage of the vertical channel transistor.

A back-gate separation pattern (or a back-gate isolation pattern) 111 may be disposed between the first active pattern AP1 and the second active pattern AP2 adjacent in the second direction D2. The back-gate separation pattern 111 may extend in the first direction D1 in parallel with the back gate electrode BG. The back-gate separation pattern 111 may be disposed on the second surface BG_S2 of the back gate electrode BG.

For example, the back-gate separation pattern 111 may include a silicon oxide film, a silicon oxynitride film, or a silicon nitride film. The back-gate separation pattern 111 may be formed at the same level as a gate separation pattern (or a gate isolation pattern) 143 that will be described below. Here, that the back-gate separation pattern 111 is formed at the same level as the gate separation pattern 143 means that the back-gate separation pattern 111 is formed by the same manufacturing process as the gate separation pattern 143. The back-gate separation pattern 111 may be formed of the same material as the gate separation pattern 143.

The back-gate separation pattern 111 may have first and second surfaces facing each other in the third direction D3. The first surface of the back-gate separation pattern 111 is closer to the bit line BL than the second surface of the back-gate separation pattern 111. In other words, the first surface of the back-gate separation pattern 111 may be a lower end surface, and the second surface of the back-gate separation pattern 111 may be an upper end surface.

For example, a height H_111 of the second surface of the back-gate separation pattern 111 based on the bit line BL may be lower than a height H_AP of the protruding portion 800 of each of the first active pattern AP1 and the second active pattern AP2 based on the bit line BL. That is, the protruding portion 800 of each of the first active pattern AP1 and the second active pattern AP2 may protrude above the second surface of the back-gate separation pattern 111.

A back-gate insulating pattern 113 may be disposed between the back gate electrode BG and the first active pattern AP1 and between the back gate electrode BG and the second active pattern AP2. The back-gate insulating pattern 113 may be disposed between the back-gate separation pattern 111 and the first active pattern AP1 and between the back-gate separation pattern 111 and the second active pattern AP2.

For example, the back-gate insulating pattern 113 may include a silicon oxide film, a silicon oxynitride film, a high dielectric constant insulating film having a higher dielectric constant than the silicon oxide film, or a combination thereof.

The back-gate insulating pattern 113 may have first and second surfaces facing each other in the third direction D3. The first surface of the back-gate insulating pattern 113 is closer to the bit line BL than the second surface of the back-gate insulating pattern 113. In other words, the first surface of the back-gate insulating pattern 113 may be a lower end surface, and the second surface of the back-gate insulating pattern 113 may be an upper end surface.

For example, a height H_113 of the second surface of the back-gate insulating pattern 113 based on the bit line BL may be lower than the height H_AP of the protruding portion 800 of each of the first active pattern AP1 and the second active pattern AP2 based on the bit line BL. That is, the protruding portion 800 of each of the first active pattern AP1 and the second active pattern AP2 may protrude above the second surface of the back-gate insulating pattern 113.

For example, the height H_113 of the second surface of the back-gate insulating pattern 113 based on the bit line BL may be the same as the height H_111 of the second surface of the back-gate separation pattern 111 based on the bit line BL. Alternatively, the height H_113 of the second surface of the back-gate insulating pattern 113 may be higher than the height H_111 of the second surface of the back-gate separation pattern 111. Alternatively, the height H_113 of the second surface of the back-gate insulating pattern 113 may be lower than the height H_111 of the second surface of the back-gate separation pattern 111.

A back-gate capping pattern 115 may be disposed between the bit line BL and the back gate electrode BG. The back-gate capping pattern 115 may be disposed between the first active pattern AP1 and the second active pattern AP2 adjacent in the second direction D2. The back-gate capping pattern 115 may extend in the first direction D1 parallel with the back gate electrode BG. The back-gate capping pattern 115 may be disposed on the first surface BG_S1 of the back gate electrode BG. A thickness of the back-gate capping pattern 115 between the bit lines BL may be different from a thickness of the back-gate capping pattern 115 on the bit line BL. The back-gate capping pattern 115 may be made of an insulating material.

For example, the back-gate capping pattern 115 may include a silicon oxide film, a silicon oxynitride film, a silicon nitride film, or a combination thereof.

The first word line WL1 and the second word line WL2 may be disposed above the bit line BL and the bit line shielding structure 171, SL, and 175. Each of the first word line WL1 and the second word line WL2 may extend in the first direction D1. The first word line WL1 and the second word line WL2 may be alternately disposed in the second direction D2.

The first word line WL1 and the second word line WL2 may be disposed between the first active pattern AP1 and the second active pattern AP2, the first word line WL1 may be disposed above the second sidewall S4 of the first active pattern AP1, and the second word line WL2 may be disposed above the first sidewall S3 of the second active pattern AP2.

The first word line WL1 is disposed to correspond to the back gate electrode BG with the first active pattern AP1 interposed therebetween. That is, the first active pattern AP1 is disposed between the first word line WL1 and the back gate electrode BG. In other words, the first word line WL1 is disposed adjacent to the second sidewall S4 of the first active pattern AP1, and the back gate electrode BG is disposed adjacent to the first sidewall S3 of the first active pattern AP1.

The second word line WL2 is disposed to correspond to the back gate electrode BG with the second active pattern AP2 interposed therebetween. That is, the second active pattern AP2 is disposed between the second word line WL2 and the back gate electrode BG. In other words, the second word line WL2 is disposed adjacent to the first sidewall S3 of the second active pattern AP2, and the back gate electrode BG is disposed adjacent to the second sidewall S4 of the second active pattern AP2.

For example, the back gate electrode BG, the second active pattern AP2, the second word line WL2, the gate separation pattern GSS, the first word line WL1, the first active pattern AP1, the back gate electrode BG, the second active pattern AP2, the second word line WL2, the gate separation pattern GSS, the first word line WL1, and the first active pattern AP1 may be sequentially disposed in the second direction D2, and this disposition may be repeated in the second direction D2.

The first word line WL1 and the second word line WL2 may be spaced apart from the bit line BL and the contact pattern BC in the third direction D3. That is, the first word line WL1 and the second word line WL2 may be disposed between the bit line BL and the contact pattern BC.

Each of the first word line WL1 and the second word line WL2 may have a width in the second direction D2. A width of the first word line WL1 and a width of the second word line WL2 above the bit line BL may be different from the width of the first word line WL1 and the width of the second word line WL2 above the bit line shielding structure 171, SL, and 175.

For example, each of the first word line WL1 and the second word line WL2 may include a first portion WLa and a second portion WLb. A width of the first portion WLa of the first word line WL1 and the second word line WL2 along the second direction D2 may be smaller than that of the second portion WLb of each of the first word line WL1 and the second word line WL2 along the second direction D2. As an example, the first portion WLa of each of the first word line WL1 and the second word line WL2 may be disposed above the bit line BL. The second portion WLb of each of the first word line WL1 and the second word line WL2 may be disposed above the bit line shielding structure 171, SL, and 175.

The first portion WLa and the second portion WLb of each of the first word line WL1 and the second word line WL2 may be alternately disposed along the first direction D1. In the first word line WL1, each of the first active patterns AP1 may be disposed between second portions WLb of first word lines WL1 adjacent in the first direction D1. In the second word line WL2, each of the second active patterns AP2 may be disposed between second portions WLb of second word lines WL2 adjacent in the first direction D1.

Each of the first word line WL1 and the second word line WL2 may have a first surface WL_S1 and a second surface WL_S2 opposed to each other in the third direction D3. The first surface WL_S1 of each of the first word line WL1 and the second word line WL2 is closer to the bit line BL than the second surface WL_S2 of each of the first word line WL1 and the second word line WL2. In other words, the first surface WL_S1 of each of the first word line WL1 and the second word line WL2 may be a lower end surface, and the second surface WL_S2 of each of the first word line WL1 and the second word line WL2 may be an upper end surface.

The first word line WL1 will be described. For example, a length of the first word line WL1 along the third direction D3 may be the same as the length of the back gate electrode BG along the third direction D3. As another example, the length of the first word line WL1 along the third direction D3 may be greater than the length of the back gate electrode BG along the third direction D3. As another example, the length of the first word line WL1 along the third direction D3 may be less than the length of the back gate electrode BG along the third direction D3.

For example, a height of the first surface WL_S1 of the first word line WL1 based on the bit line BL may be the same as a height of the first surface BG_S1 of the back gate electrode BG based on the bit line BL. As another example, the height of the first surface WL_S1 of the first word line WL1 may be greater than the height of the first surface BG_S1 of the back gate electrode BG. As another example, the height of the first surface WL_S1 of the first word line WL1 may be less than the height of the first surface BG_S1 of the back gate electrode BG.

Additionally, as an example, a height of the second surface WL_S2 of the first word line WL1 based on the bit line BL may be the same as a height of the second surface BG_S2 of the back gate electrode BG based on the bit line BL. As another example, the height of the second surface WL_S2 of the first word line WL1 may be greater than the height of the second surface BG_S2 of the back gate electrode BG. As another example, the height of the second surface WL_S2 of the first word line WL1 may be less than the height of the second surface BG_S2 of the back gate electrode BG.

Each of the first word line WL1 and the second word line WL2 may include a conductive material, and for example, each of the first and second word lines WL1 and WL2 may include doped polysilicon, conductive metal nitride, conductive metal silicon nitride, metal carbonitride, conductive metal silicide, conductive metal oxide, a two-dimensional material, a metal, or a combination thereof.

In some embodiments, the first surface WL_S1 of each of the first word line WL1 and the second word line WL2 may have various shapes. As an example, the first surface WL_S1 of each of the first word line WL1 and the second word line WL2 may be concavely rounded. Each of the first word line WL1 and the second word line WL2 may have a spacer shape. In other words, the first surface WL_S1 of each of the first word line WL1 and the second word line WL2 may be convexly rounded.

Additionally, the second surface WL_S2 of each of the first word line WL1 and the second word line WL2 may have a concave curved surface or may have a flat surface. Additionally, the first surface BG_S1 of the back gate electrode BG may have a concave curved surface or may have a flat surface. Additionally, the second surface BG_S2 of the back gate electrode BG may have a concave curved surface or may have a flat surface. The present disclosure is not limited thereto, and one of the first surface BG_S1 of the back gate electrode BG and the second surface BG_S2 of the back gate electrode BG may be flat.

A gate insulating pattern GOX may be disposed between the first word line WL1 and the first active pattern AP1 and between the second word line WL2 and the second active pattern AP2. Gate insulating patterns GOX may extend in the first direction D1 parallel to the first word line WL1 and the second word line WL2.

The gate insulating pattern GOX may include a silicon oxide film, a silicon oxynitride film, a high dielectric constant insulating film having a higher dielectric constant than the silicon oxide film, or a combination thereof.

The gate insulating pattern GOX may extend along the first sidewall S3 of the first active pattern AP1 and the second sidewall S4 of the second active pattern AP2. In the semiconductor memory device according to some embodiments, on a cross-section, the gate insulating pattern GOX between the first active pattern AP1 and the first word line WL1 may be separated from the gate insulating pattern GOX between the second active pattern AP2 and the second word line WL2.

The gate insulating pattern GOX may have first and second surfaces facing each other in the third direction D3. The first surface of the gate insulating pattern GOX is closer to the bit line BL than the second surface of the gate insulating pattern GOX. In other words, the first surface of the gate insulating pattern GOX may be a lower end surface, and the second surface of the gate insulating pattern GOX may be an upper end surface.

For example, a height H_GOX of the second surface of the gate insulating pattern GOX based on the bit line BL may be lower than the height H_AP of the protruding portion 800 of each of the first active pattern AP1 and the second active pattern AP2 based on the bit line BL. That is, the protruding portion 800 of each of the first active pattern AP1 and the second active pattern AP2 may protrude above the second surface of the gate insulating pattern GOX.

For example, the height H_GOX of the second surface of the gate insulating pattern GOX based on the bit line BL may be the same as the height H_111 of the second surface of the back-gate separation pattern 111 based on the bit line BL. Alternatively, the height H_GOX of the second surface of the gate insulating pattern GOX may be higher than the height H_111 of the second surface of the back-gate separation pattern 111. Alternatively, the height H_GOX of the second surface of the gate insulating pattern GOX may be lower than the height H_111 of the second surface of the back-gate separation pattern 111.

For example, the height H_GOX of the second surface of the gate insulating pattern GOX based on the bit line BL may be the same as the height H_113 of the second surface of the back-gate insulating pattern 113 based on the bit line BL. Alternatively, the height H_GOX of the second surface of the gate insulating pattern GOX may be higher than the height H_113 of the second surface of the back-gate insulating pattern 113. Alternatively, the height H_GOX of the second surface of the gate insulating pattern GOX may be lower than the height H_113 of the second surface of the back-gate insulating pattern 113.

The gate separation pattern 143 may be disposed between the first word line WL1 and the contact pattern BC and between the second word line WL2 and the contact pattern BC. The gate separation pattern 143 may cover the second surface WL_S2 of each of the first word line WL1 and the second word line WL2.

For example, the gate separation pattern 143 may include a silicon oxide film, a silicon oxynitride film, a silicon nitride film, or a combination thereof.

The gate separation pattern 143 may have first and second surfaces facing each other in the third direction D3. The first surface of the gate separation pattern 143 is closer to the bit line BL than the second surface of the gate separation pattern 143. In other words, the first surface of the gate separation pattern 143 may be a lower end surface, and the second surface of the gate separation pattern 143 may be an upper end surface.

For example, a height H_143 of the second surface of the gate separation pattern 143 based on the bit line BL may be lower than the height H_AP of the protruding portion 800 of each of the first active pattern AP1 and the second active pattern AP2 based on the bit line BL. That is, the protruding portion 800 of each of the first active pattern AP1 and the second active pattern AP2 may protrude above the second surface of the gate separation pattern 143.

For example, the height H_143 of the second surface of the gate separation pattern 143 based on the bit line BL may be the same as the height H_111 of the second surface of the back-gate separation pattern 111 based on the bit line BL. Alternatively, the height H_143 of the second surface of the gate separation pattern 143 may be higher than the height H_111 of the second surface of the back-gate separation pattern 111. Alternatively, the height H_143 of the second surface of the gate separation pattern 143 may be lower than the height H_111 of the second surface of the back-gate separation pattern 111.

For example, the height H_143 of the second surface of the gate separation pattern 143 based on the bit line BL may be the same as the height H_113 of the second surface of the back-gate insulating pattern 113 based on the bit line BL. Alternatively, the height H_143 of the second surface of the gate separation pattern 143 may be higher than the height H_113 of the second surface of the back-gate insulating pattern 113. Alternatively, the height H_143 of the second surface of the gate separation pattern 143 may be lower than the height H_113 of the second surface of the back-gate insulating pattern 113.

For example, the height H_143 of the second surface of the gate separation pattern 143 based on the bit line BL may be the same as the height H_GOX of the second surface of the gate insulating pattern GOX based on the bit line BL. Alternatively, the height H_143 of the second surface of the gate separation pattern 143 may be higher than the height H_GOX of the second surface of the gate insulating pattern GOX. Alternatively, the height H_143 of the second surface of the gate separation pattern 143 may be lower than the height H_GOX of the second surface of the gate insulating pattern GOX.

The gate separation pattern GSS may be disposed on the bit line BL. The gate separation pattern GSS may be disposed between the bit line BL and the contact pattern BC. The gate separation pattern GSS may contact the bit line BL.

The gate separation pattern GSS may be disposed between the first word line WL1 and the second word line WL2 adjacent to each other in the second direction D2. The first word line WL1 and the second word line WL2 may be separated by the gate separation pattern GSS. The gate separation pattern GSS may extend between the first word line WL1 and the second word line WL2 in the first direction D1.

The first word line WL1 may be disposed between the gate separation pattern GSS and the first active pattern AP1. The second word line WL2 may be disposed between the gate separation pattern GSS and the second active pattern AP2.

The gate separation pattern GSS may include a horizontal portion and a vertical portion. The vertical portion of the gate separation pattern GSS may protrude from the horizontal portion of the gate separation pattern GSS in the third direction D3.

The horizontal portion of the gate separation pattern GSS may be closer to the bit line BL than the vertical portion of the gate separation pattern GSS. The horizontal portion of the gate separation pattern GSS may contact the bit line BL. A width of the horizontal portion of the gate separation pattern GSS along the second direction D2 is greater than a width of the vertical portion of the gate separation pattern GSS along the second direction D2.

The vertical portion of the gate separation pattern GSS may be disposed between a sidewall of the first word line WL1 and a sidewall of the second word line WL2 that face each other. The horizontal portion of the gate separation pattern GSS may cover the first surface WL_S1 of each of the first word line WL1 and the second word line WL2.

The first word line WL1 and the second word line WL2 are disposed on the horizontal portion of the gate separation pattern GSS. The first word line WL1 and the second word line WL2 may be mounted on the horizontal portion of the gate separation pattern GSS. The first word line WL1 and the second word line WL2 may be disposed between the horizontal portion of the gate separation pattern GSS and the contact pattern BC.

The gate separation pattern GSS may include a gate separation liner (or a gate isolation liner) 153 and a gate separation filling film (or a gate isolation filling film) 155. The gate separation liner 153 may extend along the first surface WL_S1 of each of the first word line WL1 and the second word line WL2 and the sidewall of each of the first word line WL1 and the second word line WL2. The gate separation liner 153 may contact the gate insulating pattern GOX. Each of the gate separation liner 153 and the gate separation filling film 155 may be made of an insulating material. Unlike the drawings, the gate separation pattern GSS may be a single film.

The contact pattern BC is disposed on the first active pattern AP1 and the second active pattern AP2. The contact pattern BC may be connected to the first active pattern AP1 and the second active pattern AP2, respectively. For example, the contact pattern BC may be connected to a second face S2 of each of the first active pattern AP1 and the second active pattern AP2.

As an example, at least a portion of the protruding portion 800 of each of the first active pattern AP1 and the second active pattern AP2 may be disposed within the contact pattern BC, and the contact pattern BC may surround at least a portion of the protruding portion 800. Accordingly, a contact resistance may decrease by increasing a contact area between the first and second active patterns AP1 and AP2 and the contact pattern BC so that a time taken to read data is shortened by improving a current (or an electric current), and a misalignment between the first and second active patterns AP1 and AP2 and the contact pattern BC may be improved.

The contact pattern BC may include a conductive material, and for example, the contact pattern BC may include doped polysilicon, conductive metal nitride, conductive metal silicon nitride, metal carbonitride, conductive metal silicide, conductive metal oxide, a two-dimensional material, a metal, or a combination thereof.

As an example, the contact pattern BC may be made of a metal. In this case, as described later, the contact pattern BC with a metallic material may be formed on the first active pattern AP1 and the second active pattern AP2 to surround the protruding portion 800, so that the interface layer 830 including metal silicide is formed between the protruding portion 800 and the contact pattern BC.

If the contact pattern BC is formed by stacking undoped polysilicon and doped polysilicon that are not a metal, the contact resistance may be high, and the misalignment may occur. On the other hand, if the contact pattern BC is made of the metal and surrounds the protruding portion 800 of each of the first active pattern AP1 and the second active pattern AP2, a contact resistance may decrease by increasing a contact area between the first and second active patterns AP1 and AP2 and the contact pattern BC so that a time taken to read data is shortened by improving a current (or an electric current), and a misalignment between the first and second active patterns AP1 and AP2 and the contact pattern BC may be improved.

For example, on a plane of FIG. 2, each of contact patterns BC may have various shapes such as a circular shape, an oval shape, a rectangular shape, a square shape, a rhombic shape, a hexagonal shape, and the like.

Selectively, contact etching stop films (or contact etch stop films) 211 and 212 and a contact interlayer insulating film 231 may be sequentially stacked on the gate separation pattern 143 and the back-gate separation pattern 111. The contact etching stop films 211 and 212 may include the lower contact etching stop film 211 and the upper contact etching stop film 212. Unlike the drawings, the contact etching stop film may be a single film.

As an example, each of the contact interlayer insulating film 231, the lower contact etching stop film 211, and the upper contact etching stop film 212 may be made of an insulating material.

The contact pattern BC may penetrate the contact interlayer insulating film 231 and the contact etching stop films 211 and 212. Alternatively, the contact interlayer insulating film 231, the lower contact etching stop film 211, and the upper contact etching stop film 212 may not be disposed on the gate separation pattern 143 and the back-gate separation pattern 111. In this case, a contact separation pattern (not shown) may be disposed between the contact patterns BC. The contact separation pattern may be made of an insulating material.

As an example, the contact pattern BC may include a lower contact pattern and an upper contact pattern. The lower contact pattern may contact the first active pattern AP1 and the second active pattern AP2, and the upper contact pattern may be disposed on the lower contact pattern. A concentration of an impurity included in the lower contact pattern may be greater than a concentration of an impurity included in the upper contact pattern.

The landing pad LP may be disposed on the contact pattern BC. On a plane of FIG. 2, the landing pad LP may have various shapes such as a circular shape, an oval shape, a rectangular shape, a square shape, a rhombic shape, a hexagonal shape, and the like.

A pad separation insulating pattern may be disposed between landing pads LP. On a plane of FIG. 2, the landing pad LP may be disposed in a matrix form along the first direction D1 and the second direction D2. An upper surface of the landing pad LP may be substantially coplanar with an upper surface of the pad separation insulating pattern.

The landing pad LP may include a conductive material, and for example, the landing pad LP may include doped polysilicon, conductive metal nitride, conductive metal silicon nitride, metal carbonitride, conductive metal silicide, conductive metal oxide, a two-dimensional material, a metal, or a combination thereof.

Data storage patterns DSP may be respectively disposed on the landing pads LP. The data storage pattern DSP may be electrically connected to the first active pattern AP1 and the second active pattern AP2, respectively. As shown in FIG. 2, the data storage patterns DSP may be disposed in a matrix form along the first direction D1 and the second direction D2. The data storage pattern DSP may completely or partially overlap the landing pad LP in the third direction D3. The data storage pattern DSP may contact all or a portion of an upper surface of the landing pad LP.

As an example, the data storage pattern DSP may be a capacitor. The data storage pattern DSP may include a capacitor dielectric film 253 interposed between a storage electrode 251 and a plate electrode 255. In this case, the storage electrode 251 may contact the landing pad LP. On a plane of FIG. 2, the storage electrode 251 may have various shapes such as a circular shape, an oval shape, a rectangular shape, a square shape, a rhombic shape, a hexagonal shape, and the like. The data storage pattern DSP may completely or partially overlap the landing pad LP. The data storage pattern DSP may contact all or a portion of an upper surface of the landing pad LP. The storage electrode 251 may penetrate an upper etching stop film 247. The upper etching stop film 247 may be made of an insulating material.

Alternatively, each of the data storage patterns DSP may be a variable resistance pattern that may be switched between two resistance states by an electrical pulse applied to a memory element. For example, the data storage pattern DSP may include a phase-change material changing a crystalline state according to an amount of electrical current, a perovskite compound, transition metal oxide, a magnetic material, a ferromagnetic material, or an antiferromagnetic material.

Although not shown in the drawings, a memory cell contact plug (PLG) connected to the plate electrode 255 may be disposed on the data storage patterns DSP.

Lower peripheral contact plugs LPLGa, LPLGb, and LPLGc penetrate an element separation film STI. The lower peripheral contact plugs LPLGa, LPLGb, and LPLGc may be connected to the metal pattern 163 disposed at an end portion of the bit line BL, an end portion of the bit line shielding conductive pattern SL, and the peri wiring line 241a.

Contact plug pads PLP may be disposed on the lower peripheral contact plugs LPLGa, LPLGb, and LPLGc. A pad separation insulating pattern 245 may be disposed between the contact plug pads PLP.

Upper peripheral contact plugs PPLG penetrate an upper interlayer insulating film 270 and the upper etching stop film 247. The upper peripheral contact plugs PPLG may be disposed on the contact plug pads PLP. The upper peripheral contact plug PPLG may be connected to the contact plug pad PLP.

Each of the lower peripheral contact plugs LPLGa, LPLGb, and LPLGc, each of the contact plug pads PLP, and each of the upper peripheral contact plugs PPLG may include a conductive material, and for example, each of the lower peripheral contact plugs LPLGa, LPLGb, and LPLGc, each of the contact plug pads PLP, and each of the upper peripheral contact plugs PPLG may include doped polysilicon, conductive metal nitride, conductive metal silicon nitride, metal carbonitride, conductive metal silicide, conductive metal oxide, a two-dimensional material, a metal, or a combination thereof.

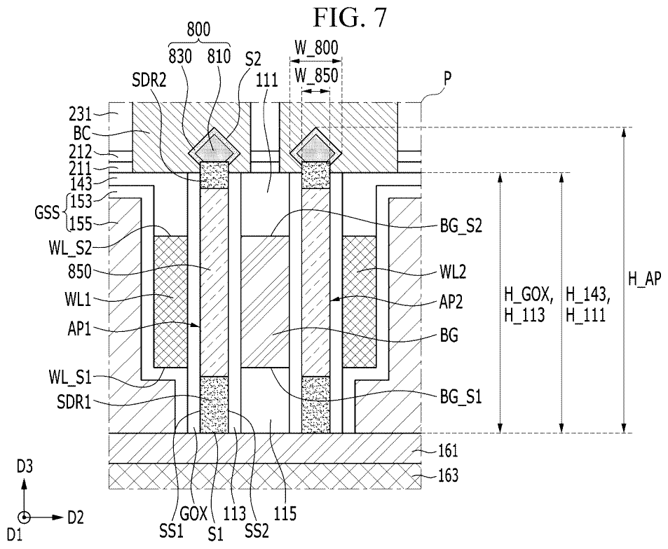

FIGS. 7 to 11 are views for describing the semiconductor memory device according to some embodiments, and are views corresponding to FIG. 5. For convenience of description, a description will be focused on differences from those described with reference to FIGS. 1 to 6.

FIG. 5 shows that the protruding portion 800 of each of the first active pattern AP1 and the second active pattern AP2 includes the central portion 810 including a monocrystalline semiconductor material that is not doped with an impurity, the surface layer portion 820 surrounding the central portion 810 and including a monocrystalline semiconductor material doped with an impurity, and the interface layer 830 surrounding the surface layer portion 820 and including metal silicide.

Referring to FIG. 7, in the semiconductor memory device according to some embodiments, the protruding portion 800 of each of the first active pattern AP1 and the second active pattern AP2 includes the central portion 810 including the monocrystalline semiconductor material that is not doped with the impurity, and the interface layer 830 surrounding the central portion 810 and including metal silicide.

That is, the protruding portion 800 of each of the first active pattern AP1 and the second active pattern AP2 may not include the surface layer portion 820 surrounding the central portion 810 and including the monocrystalline semiconductor material doped with the impurity. In this time, the second dopant region SDR2 of the body portion 850 may be connected to the central portion 810 of the protruding portion 800.

As described later, the central portion 810 may be formed by performing a first selective epitaxial growth using a source gas of a semiconductor material that does not include an impurity gas, and then the second dopant region SDR2 may be formed by doping an impurity in an upper end of the body portion 850 using gas phase diffusion (GPD) or ion implantation.

Accordingly, the protruding portion 800 of each of the first active pattern AP1 and the second active pattern AP2 may not include the surface layer portion 820, and the second dopant region SDR2 of the body portion 850 may be connected to the central portion 810 of the protruding portion 800.

In this case, the protruding portion 800 may further include the interface layer 830 surrounding the central portion 810. As described later, the contact pattern BC with a metallic material may be formed on the first active pattern AP1 and the second active pattern AP2 to surround the protruding portion 800, so that the interface layer 830 including metal silicide is formed between the protruding portion 800 and the contact pattern BC. That is, the interface layer 830 may be disposed between the central portion 810 of the protruding portion 800 and the contact pattern BC.

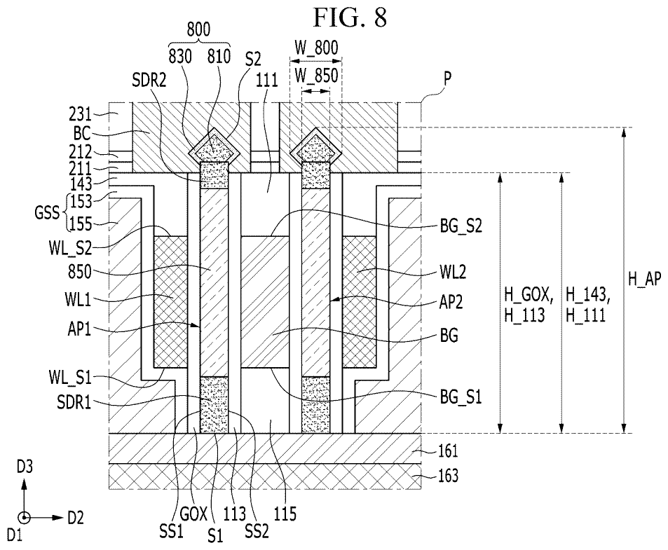

Referring to FIG. 8, in the semiconductor memory device according to some embodiments, the protruding portion 800 of each of the first active pattern AP1 and the second active pattern AP2 includes the central portion 810 including a monocrystalline semiconductor material doped with an impurity, and the interface layer 830 surrounding the central portion 810 and including metal silicide.

That is, the protruding portion 800 of each of the first active pattern AP1 and the second active pattern AP2 may include the central portion 810 including the monocrystalline semiconductor material doped with the impurity, and may not include the surface layer portion 820 surrounding the central portion 810 and including the monocrystalline semiconductor material doped with the impurity. In this time, the second dopant region SDR2 of the body portion 850 may be connected to the central portion 810 of the protruding portion 800.

As described later, in a process in which the central portion 810 is formed by performing a first selective epitaxial growth using a source gas of a semiconductor material that includes an impurity gas and then the surface layer portion 820 is formed by annealing the grown epitaxial, an impurity of the body portion 850 may be doped to an upper end of the body portion 850 through the annealing to form the second dopant region SDR2 of the body portion 850. Alternatively, the central portion 810 may be formed by performing the first selective epitaxial growth using the source gas of the semiconductor material that includes the impurity gas, and then the second dopant region SDR2 may be formed by directly doping an impurity using gas phase diffusion (GPD) or ion implantation.

Accordingly, the protruding portion 800 of each of the first active pattern AP1 and the second active pattern AP2 may include the central portion 810 including the monocrystalline semiconductor material doped with the impurity, may not include the surface layer portion 820, and the second dopant region SDR2 of the body portion 850 may be connected to the central portion 810 of the protruding portion 800.

In this case, the protruding portion 800 may further include the interface layer 830 surrounding the central portion 810. As described later, the contact pattern BC with a metallic material may be formed on the first active pattern AP1 and the second active pattern AP2 to surround the protruding portion 800, so that the interface layer 830 including metal silicide is formed between the protruding portion 800 and the contact pattern BC. That is, the interface layer 830 may be disposed between the central portion 810 of the protruding portion 800 and the contact pattern BC.

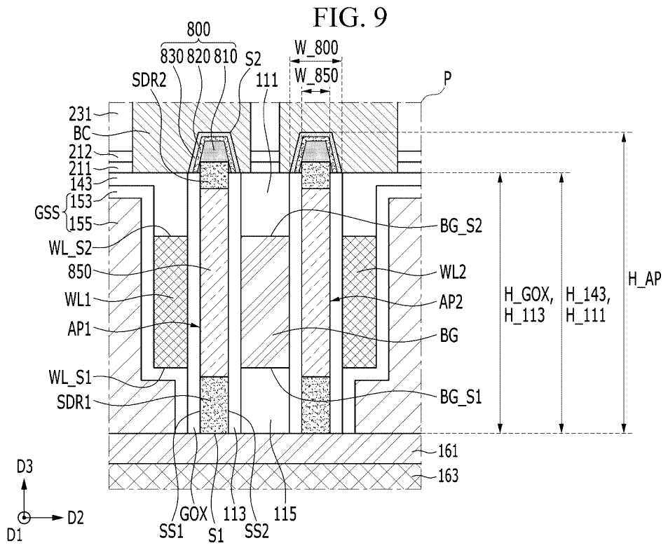

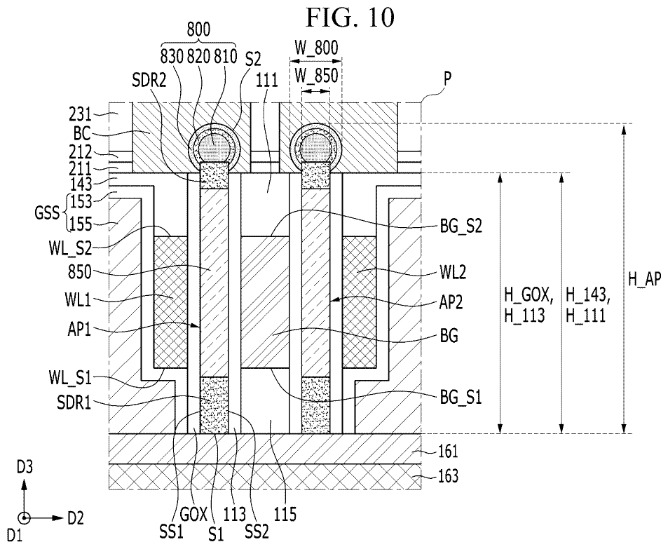

FIG. 5 shows that the protruding portion 800 has a rhombus cross-section shape. In FIG. 9, the protruding portion 800 is shown as having a trapezoid cross-section shape, and in FIG. 10, the protruding portion 800 is shown as having a circular cross-section shape. For example, the protruding portion 800 may have a circular, elliptical, or polygonal cross-sectional shape. Here, for example, the polygonal cross-sectional shape may be a triangle, a quadrangle, a pentagon, a hexagon, a rhombus, or a trapezoid.

In FIG. 5, a lower end surface of the contact pattern BC is flat, and a height (H_BC) of the lower end surface of the contact pattern BC based on the bit line BL may be lower than the height H_AP of the protruding portion 800 of each of the first active pattern AP1 and the second active pattern AP2 based on the bit line BL, but FIG. 5 shows that height (H_BC) of the lower end surface of the contact pattern BC is the same as the height H_111 of the second surface of the back-gate separation pattern 111, the height H_143 of the second surface of the gate separation pattern 143, the height H_113 of the second surface of the back-gate insulating pattern 113, and the height H_GOX of the second surface of the gate insulating pattern GOX.

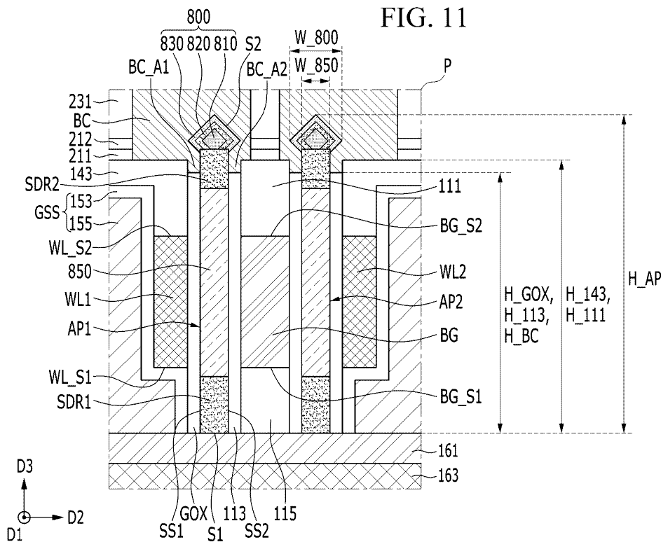

Referring to FIG. 11, in the semiconductor memory device according to some embodiments, the contact pattern BC may include a first extension portion BC_A1 and a second extension portion BC_A2 protruding toward the first active pattern AP1 or the second active pattern AP2.

The first extension portion BC_A1 of the contact pattern BC is disposed between the first active pattern AP1 or second active pattern AP2 and the gate separation pattern 143. The first extension portion BC_A1 of the contact pattern BC protrudes toward the gate insulating pattern GOX to be disposed above the gate insulating pattern GOX in the third direction D3.

The second extension portion BC_A2 of the contact pattern BC is disposed between the first active pattern AP1 or second active pattern AP2 and the back-gate separation pattern 111. The first extension portion BC_A1 of the contact pattern BC protrudes toward the gate insulating pattern GOX to be disposed above the gate insulating pattern GOX in the third direction D3.

The first extension portion BC_A1 of the contact pattern BC may have a lower end surface in contact with the gate insulating pattern GOX, and the second extension portion BC_A2 of the contact pattern BC may have a lower end surface in contact with the gate insulating pattern GOX.

For example, a height H_BC of the lower end surface of each of the first extension portion BC_A1 and the second extension portion BC_A2 based on the bit line BL may be lower than the height H_AP of the protruding portion 800 of each of the first active pattern AP1 and the second active pattern AP2 based on the bit line BL. That is, the protruding portion 800 of each of the first active pattern AP1 and the second active pattern AP2 may protrude above the lower end surface of each of the first extension portion BC_A1 and the second extension portion BC_A2. That is, the protruding portion 800 of each of the first active pattern AP1 and the second active pattern AP2 is disposed between the first extension portion BC_A1 and the second extension portion BC_A2 of the contact pattern BC. Accordingly, at least a portion of the protruding portion 800 of each of the first active pattern AP1 and the second active pattern AP2 may be surrounded by the first extension portion BC_A1 and the second extension portion BC_A2 of the contact pattern BC.

For example, the height H_BC of the lower end surface of each of the first extension portion BC_A1 and the second extension portion BC_A2 based on the bit line BL may be lower than the height H_111 of the second surface of the back-gate separation pattern 111 based on the bit line BL. Additionally, the height H_BC of the lower end surface of each of the first extension portion BC_A1 and the second extension portion BC_A2 based on the bit line BL may be lower than the height H_143 of the second surface of the gate separation pattern 143 based on the bit line BL.

As an example, the height H_BC of the lower end surface of each of the first extension portion BC_A1 and the second extension portion BC_A2 based on the bit line BL may be the same as the height H_113 of the second surface of the back-gate insulating pattern 113 based on the bit line BL. In addition, the height H_BC of the lower end surface of each of the first extension portion BC_A1 and the second extension portion BC_A2 based on the bit line BL may be the same as the height H_GOX of the second surface of the gate insulating pattern GOX based on the bit line BL.

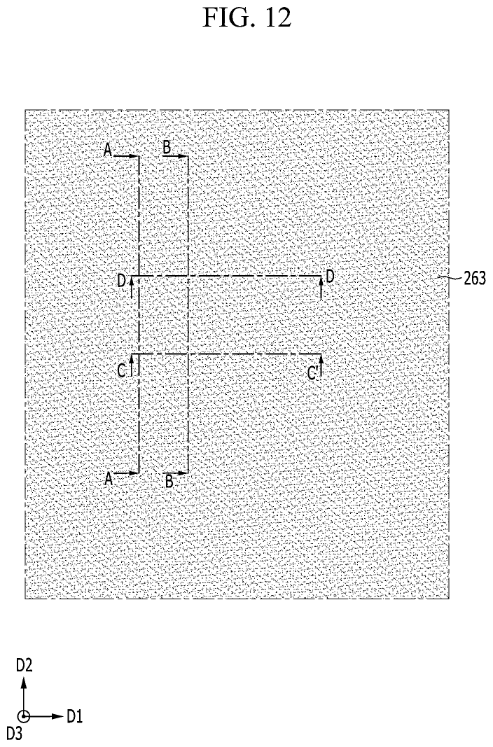

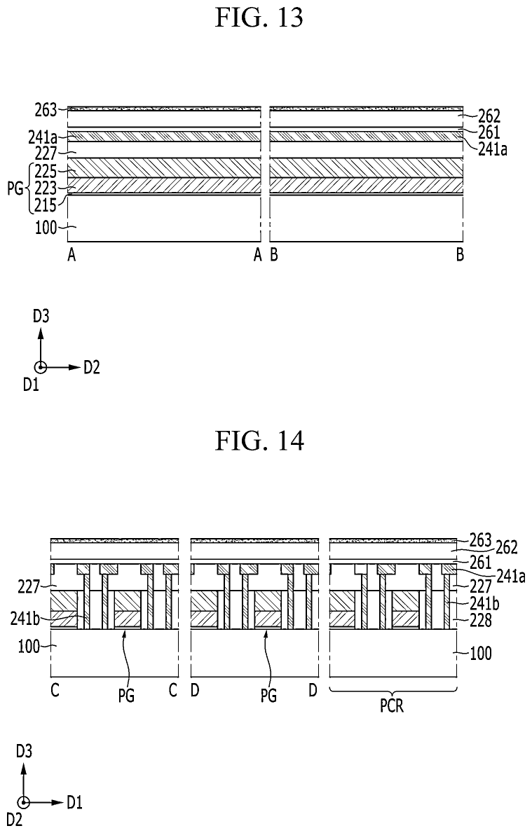

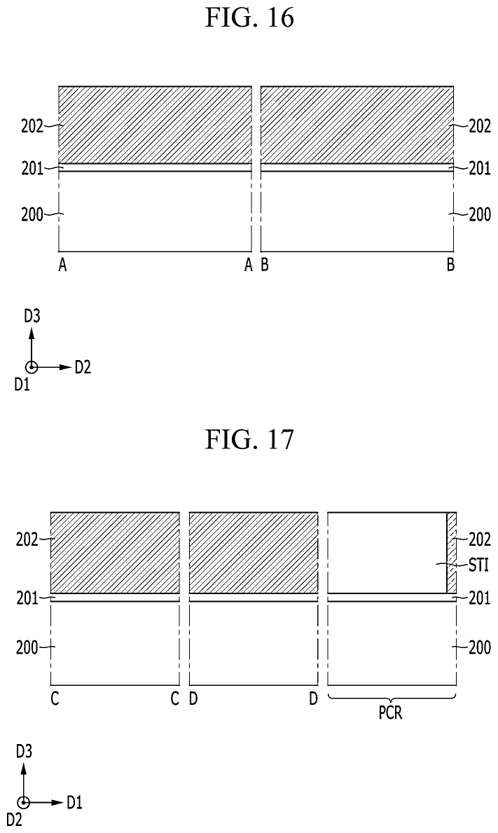

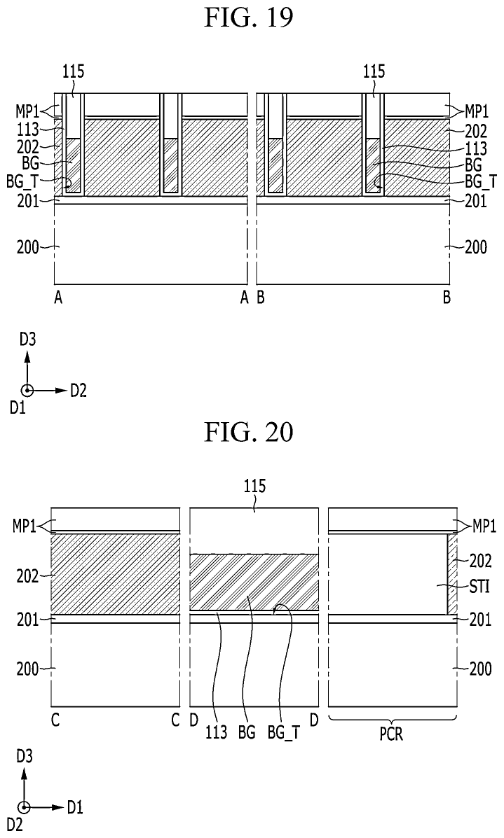

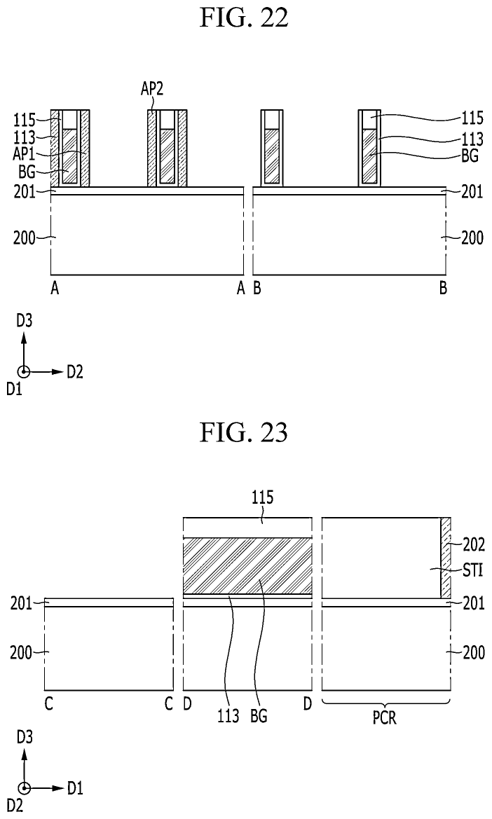

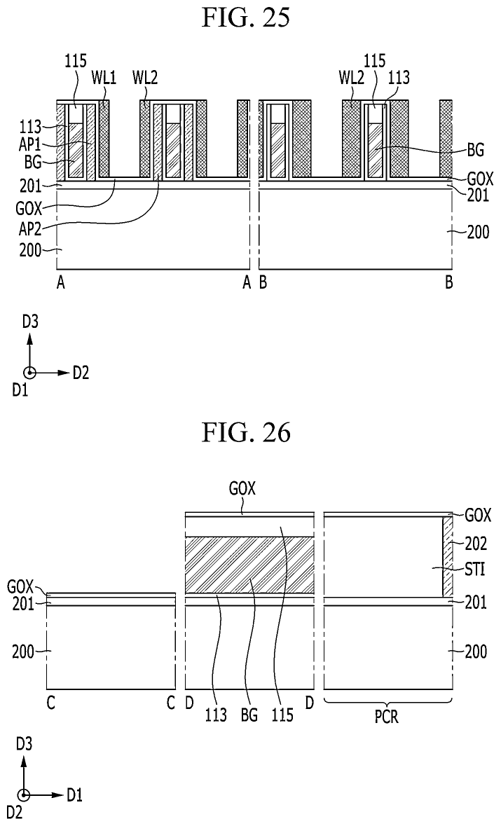

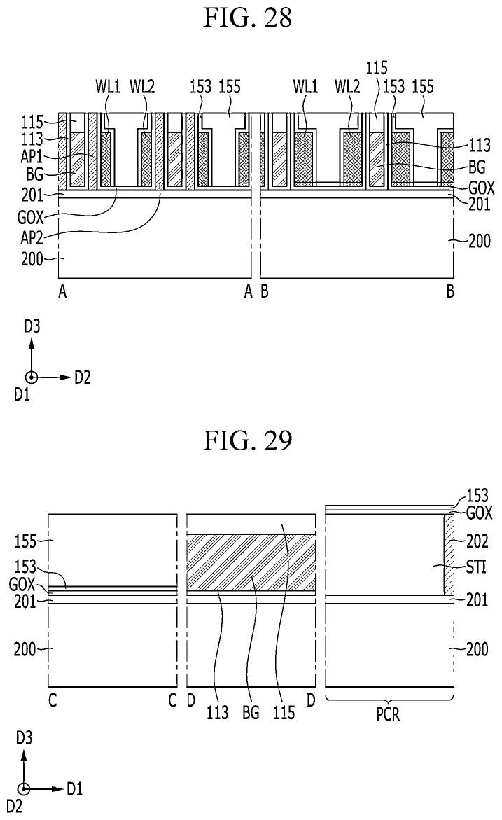

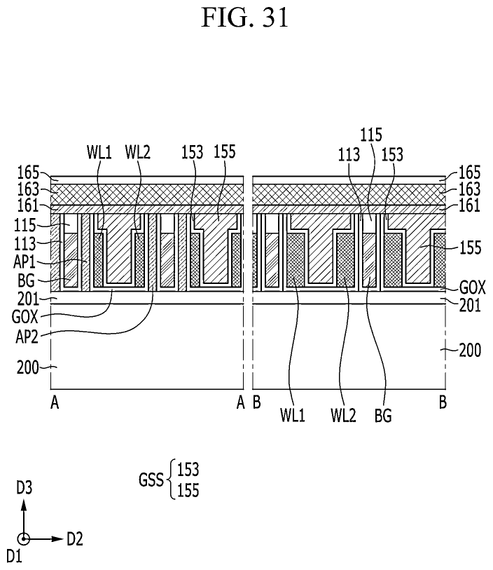

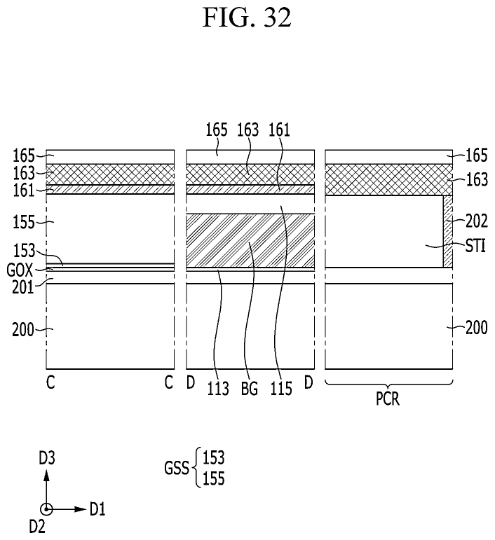

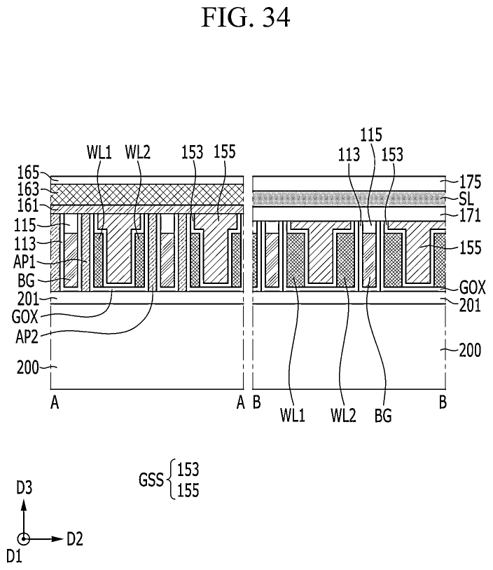

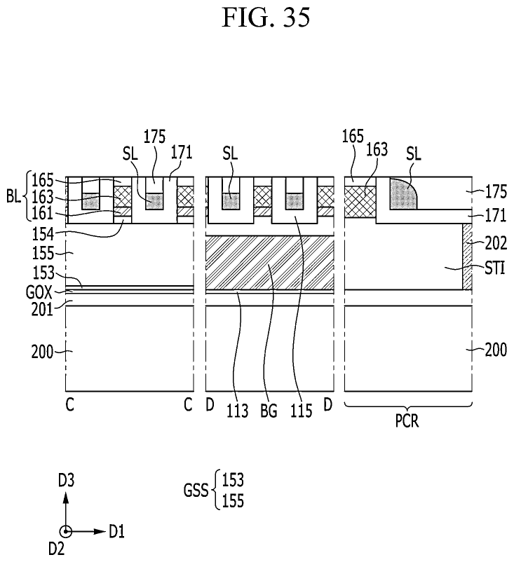

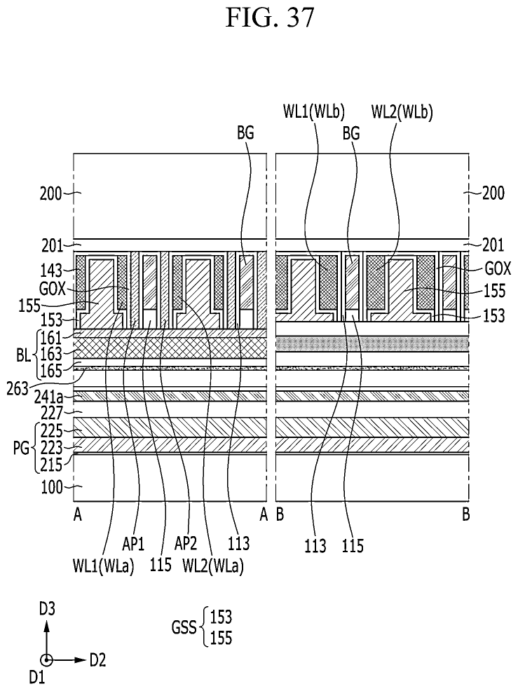

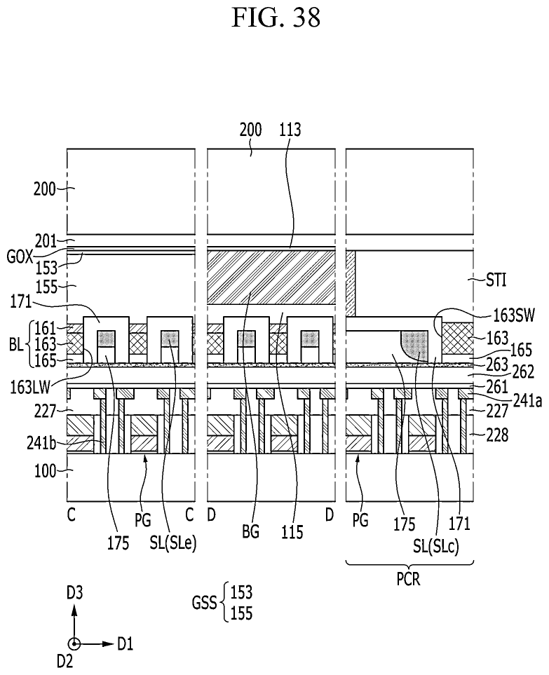

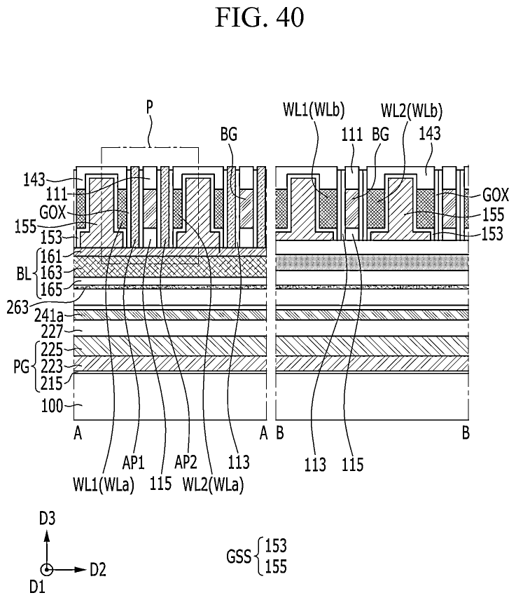

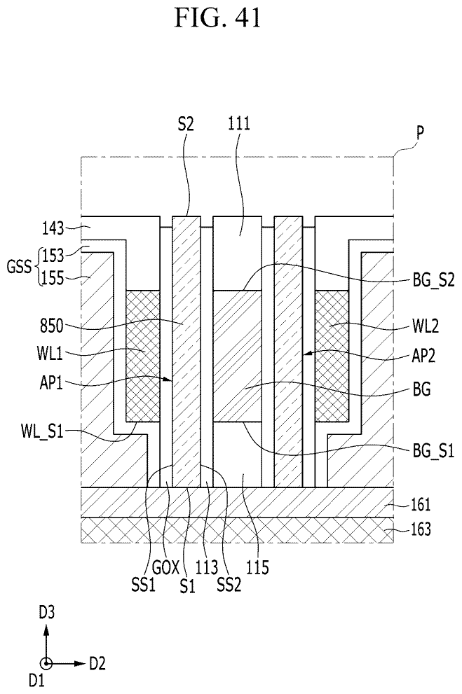

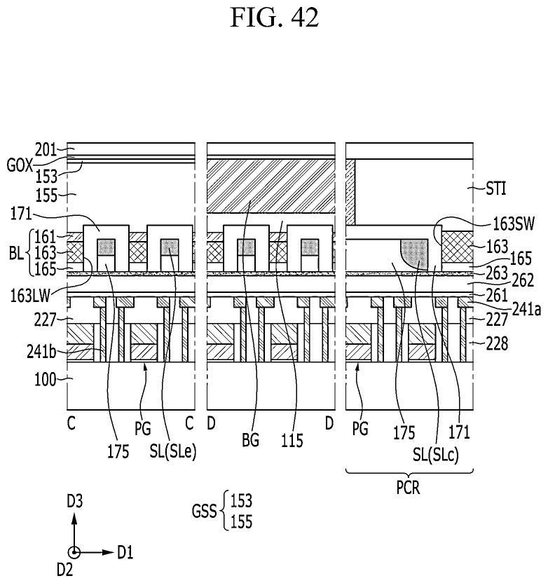

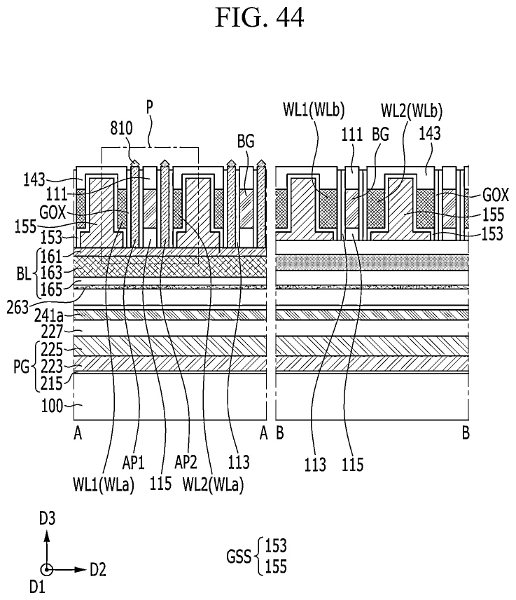

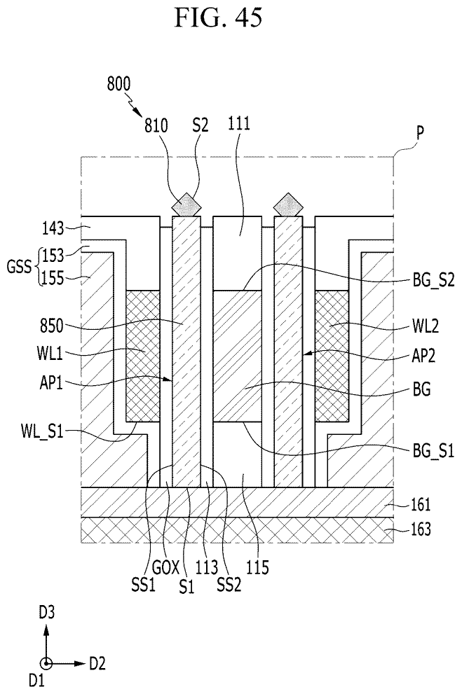

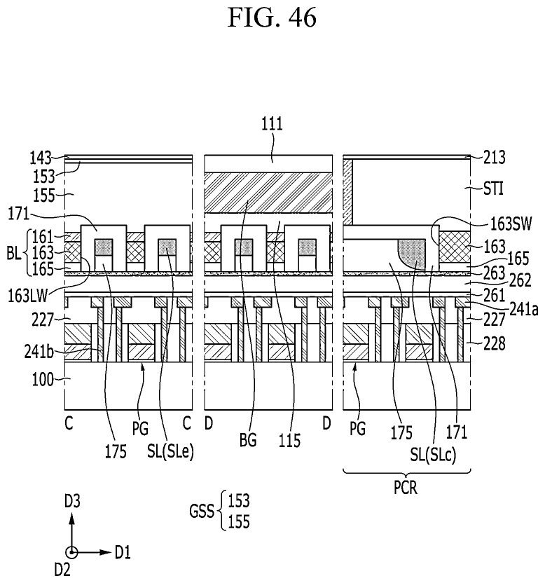

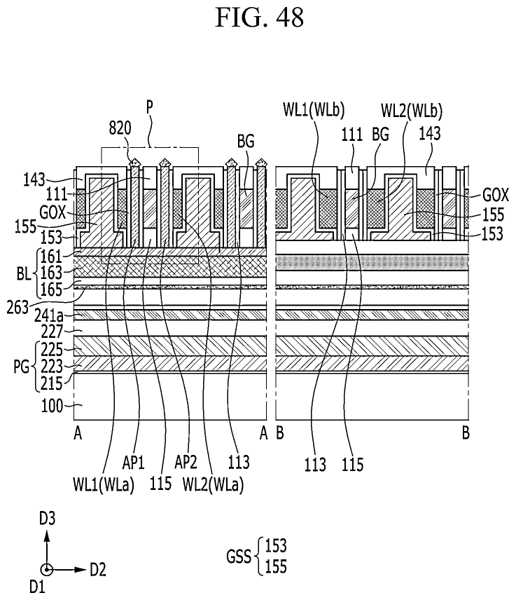

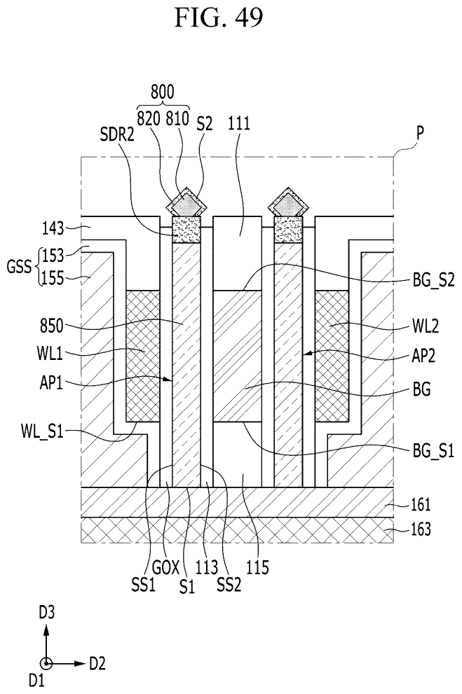

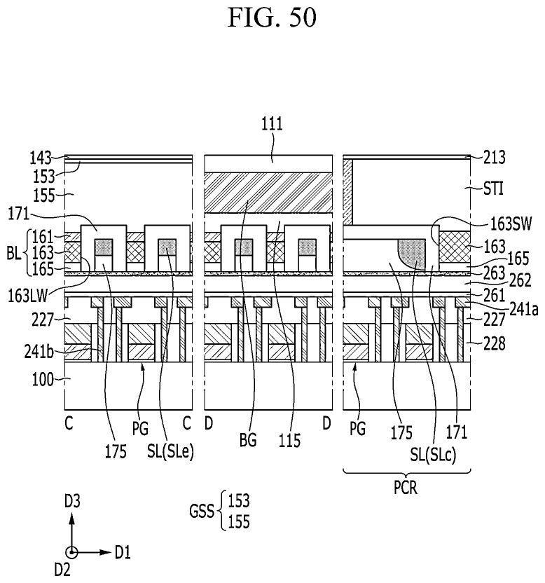

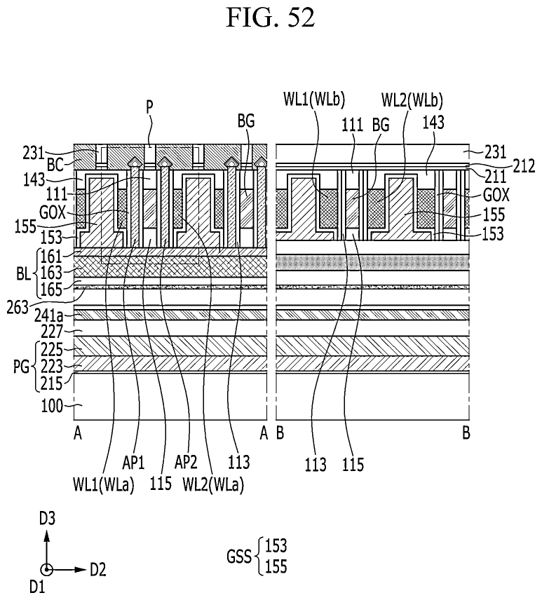

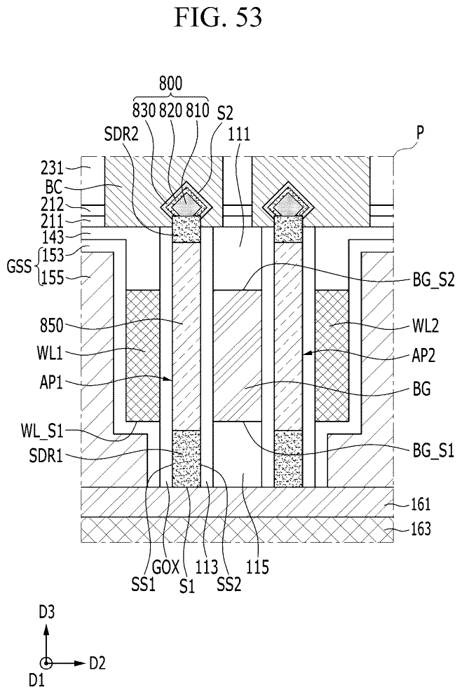

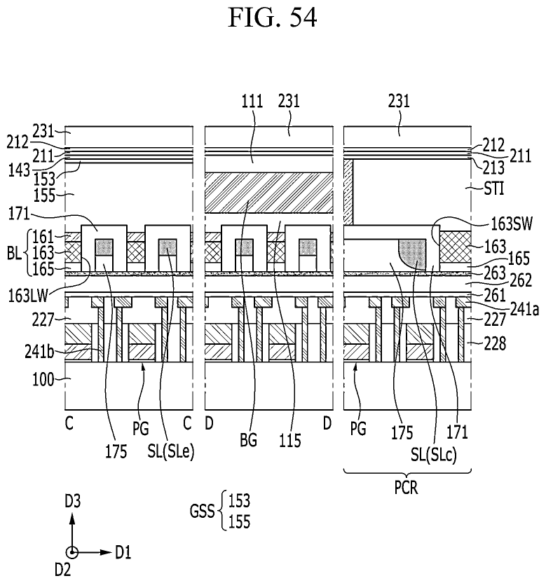

FIGS. 12 to 54 are views for describing a method for manufacturing the semiconductor memory device according to some embodiments.

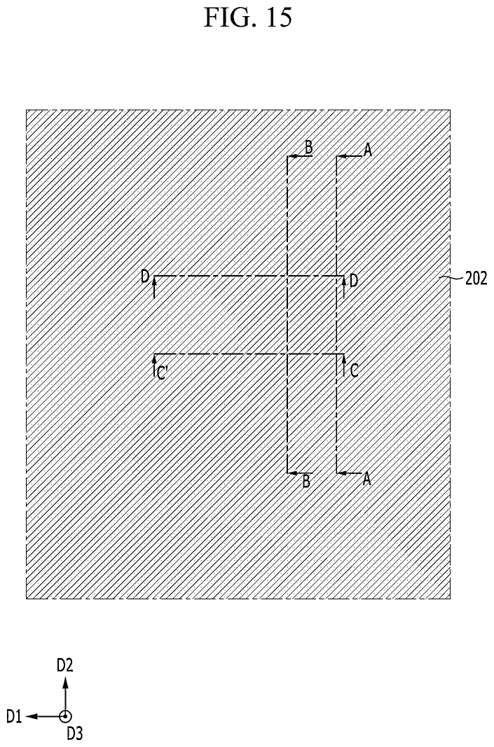

For reference, a cutting line and a coordinate system shown in FIGS. 15 to 35 are a cutting line and a coordinate system obtained by inverting a cutting line and a coordinate system of FIG. 2 in the first direction D1.

Referring to FIGS. 12 to 14, the peripheral gate structure PG may be formed on the substrate 100.

The peri wiring line 241a and the peri contact plug 241b may be formed above or on the substrate 100. The first peri upper insulating film 261 and the second peri upper insulating film 262 may be sequentially formed above or on the peri wiring line 241a and the peri contact plug 241b. The bonding insulating film 263 may be formed on the second peri upper insulating film 262.

Referring to FIGS. 15 to 17, a sub-substrate structure including a sub-substrate 200, a buried insulating layer 201, and an active layer 202 is formed.

The buried insulating layer 201 and the active layer 202 may be provided above or on the sub-substrate 200. The sub-substrate 200, the buried insulating layer 201, and the active layer 202 may be a silicon-on-insulator (SOI) substrate.

The sub-substrate 200 may include the cell array region CAR and the peripheral circuit region PCR. For example, the sub-substrate 200 may be a silicon substrate, a germanium substrate, and/or a silicon-germanium substrate.

The buried insulating layer 201 may be buried oxide (BOX) formed by a separation by implanted oxygen (SIMOX) method or a bonding and layer transfer method. Alternatively, the buried insulating layer 201 may be an insulating film formed by a chemical vapor deposition method. For example, the buried insulating layer 201 may include a silicon oxide film, a silicon nitride film, a silicon oxynitride film, and/or a low dielectric constant insulating film.

The active layer 202 may be a monocrystalline semiconductor film. For example, the active layer 202 may be a monocrystalline silicon substrate, a monocrystalline germanium substrate, and/or a monocrystalline silicon-germanium substrate. The active layer 202 may have a first surface and a second surface opposed to each other in the third direction D3, and the second surface of the active layer 202 may contact the buried insulating layer 201.

The element separation film STI may be formed within the active layer 202 of the peripheral circuit region PCR. The element separation film STI may be formed by patterning the active layer 202 of the peripheral circuit region PCR to form an element separation trench that exposes the buried insulating layer 201 and then burying an insulating material within the element separation trench.

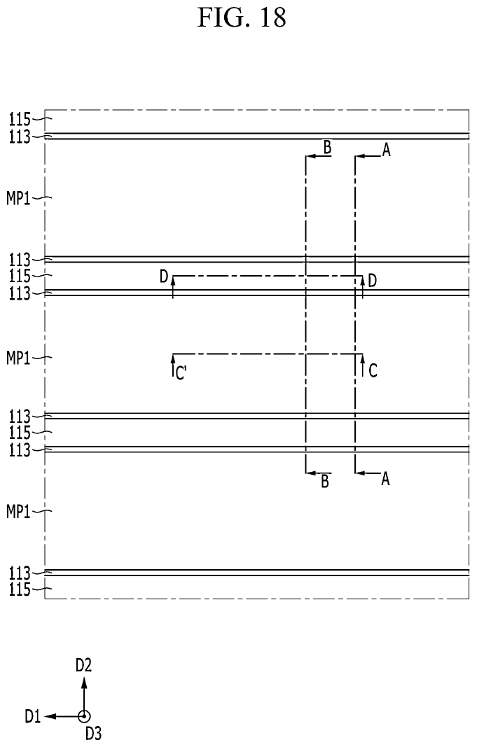

Referring to FIGS. 18 to 20, the back gate electrode BG is formed within the active layer 202.

First, a first mask pattern MP1 may be formed on the active layer 202.

The first mask pattern MP1 may include line-shaped openings extending along the first direction D1 in the cell array region CAR. The first mask pattern MP1 may include a first lower mask film and a first upper mask film 12 sequentially stacked. The first upper mask film 12 may be made of a material that has an etching selectivity with respect to the first lower mask film. For example, the first lower mask film may include silicon oxide, and the first upper mask film 12 may include silicon nitride, but the present disclosure is not limited thereto.

Subsequently, the active layer 202 of the cell array region CAR may be anisotropic-etched using the first mask pattern MP1 as an etching mask. Accordingly, back gate trenches BG_T extending in the first direction D1 may be formed in the active layer 202 of the cell array region CAR. The back gate trenches BG_T may expose the buried insulating layer 201, and may be spaced apart at regular intervals in the second direction D2.

Subsequently, the back-gate insulating pattern 113 and the back gate electrode BG may be formed within the back gate trench BG_T.

More specifically, the back-gate insulating pattern 113 may be formed along a sidewall and a bottom surface of the back gate trench BG_T and an upper surface of the first mask pattern MP1. A back-gate conductive film may be formed on the back-gate insulating pattern 113. The back-gate conductive film may fill the back gate trench BG_T. Next, the back-gate conductive film may be isotropically etched so that the back gate electrode BG extending in the first direction D1 is formed. The back gate electrode BG may fill a portion of the back gate trench BG_T.

Subsequently, each of back-gate capping patterns 115 may be formed on the back gate electrode BG.

The back-gate capping pattern 115 may fill the remainder of the back gate trench BG_T. If the back-gate capping pattern 115 and the back-gate insulating pattern 113 are made of the same material (e.g., silicon oxide), the back-gate insulating pattern 113 on the upper surface of the first mask pattern MP1 may be removed while the back-gate capping pattern 115 is formed.

After the back-gate capping patterns 115 are formed, the first upper mask film 12 may be removed. The back-gate capping patterns 115 may have a shape that protrudes above an upper surface of the first lower mask film.

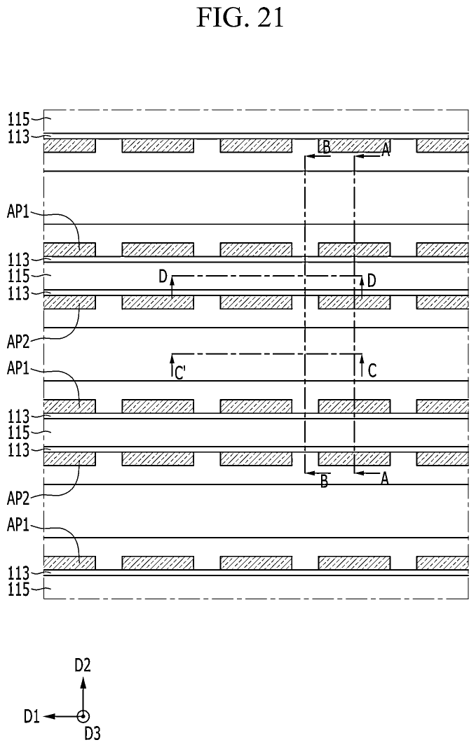

Referring to FIGS. 21 to 23, the first active pattern AP1 and the second active pattern AP2 are formed at both sides of the back gate electrode BG.

First, a spacer film may be formed along an upper surface of the first lower mask film, sidewalls of the back-gate insulating patterns 113, and upper surfaces of the back-gate capping patterns 115. The spacer film may be formed to have a uniform thickness. Widths of active patterns of vertical channel transistors may be determined depending on a deposition thickness of the spacer film. The spacer film may be made of an insulating material. For example, the spacer film may include silicon oxide, silicon oxynitride, silicon nitride, silicon carbide (SiC), silicon carbon nitride (SiCN), a combination thereof, or the like.

Subsequently, a peripheral mask pattern that exposes the cell array region CAR may be formed on the spacer film of the peripheral circuit region PCR.

Subsequently, a pair of spacer patterns may be formed on a sidewall of the back-gate insulating pattern 113 by performing an anisotropic etching process on the spacer film.

An anisotropic etching process may be performed on the active layer 202 using the spacer pattern as an etching mask. Through this, a pair of pre-active patterns separated from each other may be formed at both sides of each back-gate insulating pattern 113. The buried insulating layer 201 may be exposed by forming the pre-active patterns.

Each of the pre-active patterns may have a line shape extending in the first direction D1 parallel to the back gate electrode BG. A word line trench may be formed between the pre-active patterns adjacent to each other in the second direction D2.

After the spacer pattern is formed, the peripheral mask pattern may be removed. A portion of the spacer film may remain on the first lower mask film of the peripheral circuit region PCR.

Subsequently, an etching stop film may be formed along a sidewall and a bottom surface of the word line trench. A sacrificial film that fills the word line trench in which the etching stop film is formed may be formed. The sacrificial film may fill the word line trench. The sacrificial film may have a substantially flat upper surface.

The etching stop film may be formed by depositing an insulating material (for example, silicon oxide), but the present disclosure is not limited thereto. The sacrificial film may be formed of an insulating material with an etching selectivity with respect to the etching stop film. As an example, the sacrificial film may be one of an insulating material and a silicon oxide film formed using spin-on-glass (SOG) technology, but the present disclosure is not limited thereto.

The etching stop film and the sacrificial film may be sequentially stacked on the spacer film of the peripheral circuit region PCR.

Subsequently, a second mask pattern may be formed on the sacrificial film.

The second mask pattern may be formed of a material with an etching selectivity with respect to the sacrificial film. The second mask pattern may have a line shape that extends in the second direction D2.

Next, openings OPs may be formed by etching the sacrificial film using the second mask pattern as an etching mask. The openings may expose the etching stop film.

Subsequently, the etching stop film exposed by the openings may be removed.

The openings may expose an upper surface of the buried insulating layer 201. Additionally, the openings may expose portions of the pre-active patterns.

Next, the pre-active patterns exposed by the openings may be etched so that the first active pattern AP1 and the second active pattern AP2 are formed at both sides of the back gate electrode BG. The first active patterns AP1 may be formed spaced apart from each other in the first direction D1 above the first sidewall of the back gate electrode BG. The second active patterns AP2 may be formed spaced apart from each other in the first direction D1 above the second sidewall of the back gate electrode BG. Because the first active pattern AP1 and the second active pattern AP2 are formed, the openings may expose a portion of the back-gate insulating pattern 113.

Then, the sacrificial layer may be filled within the openings. The sacrificial film that fills the opening may be the same material as the sacrificial film that fills the word line trench.

After the sacrificial film is filled within the opening, the second mask pattern may be removed. A planarization process may be performed on the sacrificial film and the etching stop film so that an upper surface of the back-gate capping pattern 115 is exposed. Next, the spacer pattern and the first lower mask film may be removed. Through this, the first active pattern AP1 and the second active pattern AP2 may be exposed. The spacer pattern and the first lower mask film may be removed using a planarization process, but the present disclosure is not limited thereto.

Subsequently, the sacrificial film and the etching stop film on the buried insulating layer 201 may be removed. Through this, the buried insulating layer 201 may be exposed.

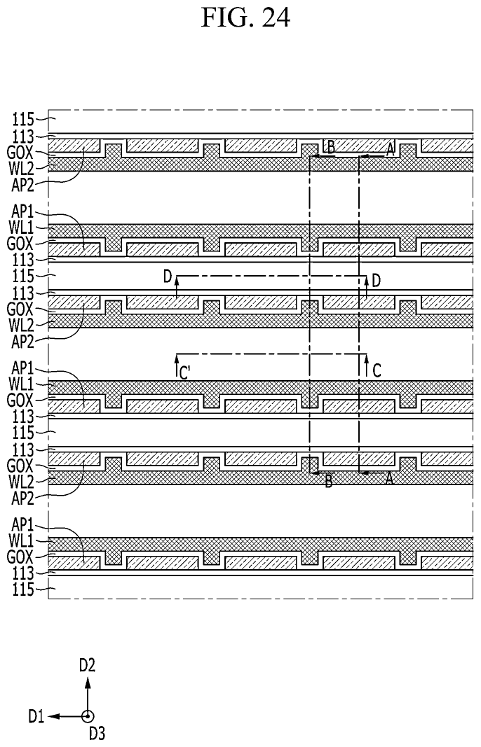

Referring to FIGS. 24 to 26, the first word line WL1 and the second word line WL2 may be formed on the gate insulating pattern GOX.

First, the gate insulating pattern GOX may be formed along the sidewall of the first active pattern AP1, the sidewall of the second active pattern AP2, an upper surface of the back-gate capping pattern 115, and an upper surface of the buried insulating layer 201.

The gate insulating pattern GOX may be deposited on the active layer 202 and the element separation film STI in the peripheral circuit region PCR. The gate insulating pattern GOX may be formed using at least one of physical vapor deposition (PVD) technology, thermal chemical vapor deposition (CVD) technology, low pressure chemical vapor deposition (LP-CVD) technology, plasma enhanced chemical vapor deposition (PE-CVD) technology, and atomic layer deposition (ALD) technology, but the present disclosure is not limited thereto.

Subsequently, the first word line WL1 and the second word line WL2 may be formed on the gate insulating pattern GOX. The first and second word lines WL1 and WL2 may be formed above the sidewalls of the first and second active patterns AP1 and AP2.

Forming the first and second word lines WL1 and WL2 may include depositing a gate conductive film on the gate insulating pattern GOX and then performing an anisotropic etching process on the gate conductive film. Here, a deposition thickness of the gate conductive film may be less than half a width of the word line trench.

During the anisotropic etching process on the gate conductive film, the gate insulating pattern GOX may be used as an etching stop film. Unlike the drawings, the gate conductive film may be over-etched so that the buried insulating layer 201 is exposed. The first word line WL1 and the second word line WL2 may have various shapes depending on the anisotropic etching process on the gate conductive film. For example, an upper surface of the first word line WL1 and an upper surface of the second word line WL2 may be disposed at a lower level than upper surfaces of the first and second active patterns AP1 and AP2.

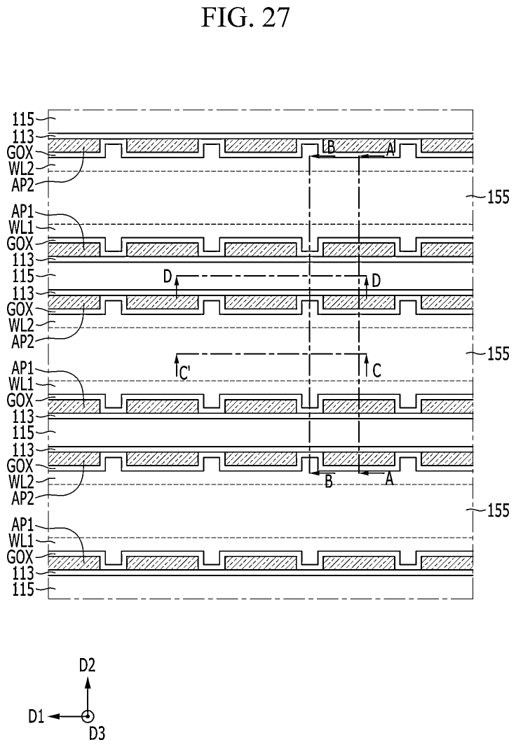

Referring to FIGS. 27 to 29, the gate separation liner 153 and the gate separation filling film 155 are formed above or on the first word line WL1 and the second word line WL2.

First, the gate separation liner 153 may be formed above the sub-substrate 200. For example, the gate separation liner 153 may include a silicon nitride (SIN) film, a silicon oxynitride (SiON) film, a silicon carbide (SiC) film, a silicon carbon nitride (SiCN) film, or a combination thereof. The gate separation liner 153 may cover may cover surfaces of the word lines WL1 and WL2.

Subsequently, the gate separation filling film 155 may be formed to fill the word line trench where the gate separation liner 153 is formed. Here, the gate separation filling film 155 may be made of an insulating material different from that of the gate separation liner 153. Thereafter, a planarization process may be performed on the gate separation liner 153 and the gate separation filling film 155 so that upper surfaces of the back-gate capping patterns 115 are exposed.

On the other hand, before the gate separation filling film 155 is formed, a mask pattern exposing the cell array region CAR may be formed on the gate separation liner 153 of the peripheral circuit region PCR. In this case, the gate separation filling film 155 may not be formed in the peripheral circuit region PCR.

Subsequently, the first dopant region SDR1 may be formed within the first active pattern AP1 and the second active pattern AP2.

An impurity may be doped into a portion of the first active pattern AP1 and a portion of the second active pattern AP2 so that the first dopant region SDR1 is formed.

Forming the first dopant region SDR1 may be an optional process. A subsequent manufacturing method will be described using a case where the first dopant region SDR1 is not formed.

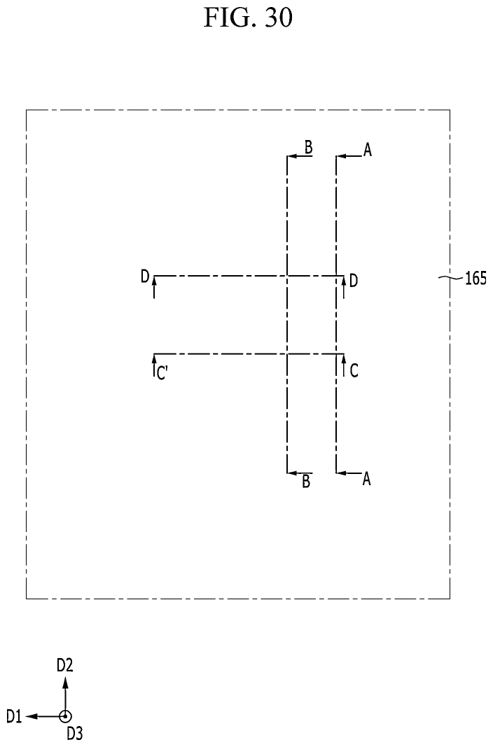

Referring to FIGS. 30 to 32, the polysilicon pattern 161, the metal pattern 163, and the bit line mask pattern 165 are sequentially stacked above a front surface of the sub-substrate 200.

First, the polysilicon pattern 161 may be formed above the front surface of the sub-substrate 200.

The polysilicon pattern 161 may contact the first and second active patterns AP1 and AP2 in the cell array region CAR. The polysilicon pattern 161 may be formed on the element separation film STI in the peripheral circuit region PCR.

Subsequently, a third mask pattern that exposes the peripheral circuit region PCR may be formed on the polysilicon pattern 161. The polysilicon pattern 161 of the peripheral circuit region PCR may be removed using the third mask pattern as an etching mask. The element separation film STI may be exposed in the peripheral circuit region PCR.

Subsequently, the metal pattern 163 and the bit line mask pattern 165 may be formed above or on the polysilicon pattern 161 of the cell array region CAR.

The metal pattern 163 and the bit line mask pattern 165 may be formed on the element separation film STI of the peripheral circuit region PCR.

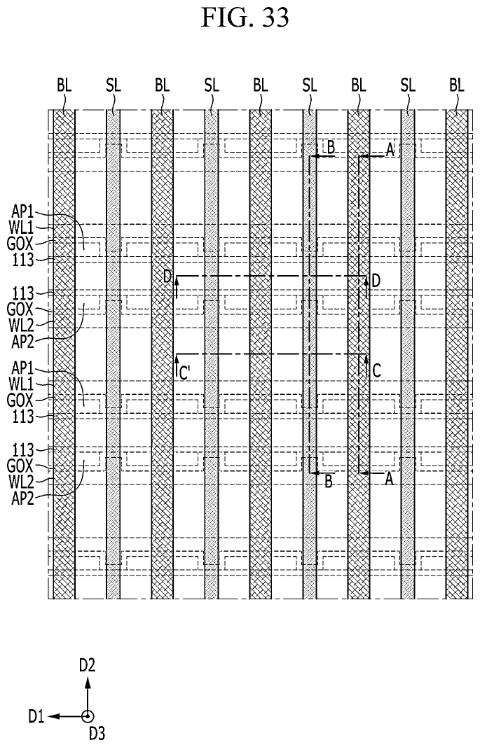

Referring to FIGS. 33 to 35, the bit line BL extending in the second direction D2 may be formed by patterning the bit line mask pattern 165, the metal pattern 163, and the polysilicon pattern 161.

While the bit line BL is formed, a portion of the back-gate capping pattern 115 may be etched. Additionally, while the bit line BL is formed, the element separation film STI of the peripheral circuit region PCR may be etched. Through this, a portion of the element separation film STI and the active layer 202 may be exposed.

Subsequently, the bit line shielding insulating liner 171 may be formed on the bit line BL. The bit line shielding insulating liner 171 may define a bit line shielding region between the bit lines BL.

The bit line shielding insulating liner 171 may have a substantially uniform thickness. The bit line shielding insulating liner 171 may be formed above a front surface of the sub-substrate 200. A deposition thickness of the bit line shielding insulating liner 171 may be less than half a distance at which the bit lines BL are spaced apart. As the bit line shielding insulating liner 171 is formed, the bit line shielding region may be defined between the bit lines BL by the bit line shielding insulating liner 171. The bit line shielding region may extend in the second direction D2 parallel to the bit line BL.

After the bit line shielding insulating liner 171 is formed, the bit line shielding conductive pattern SL may be formed within the bit line shielding region of the bit line shielding insulating liner 171.

The bit line shielding conductive pattern SL may be formed between the bit lines BL. For example, forming the bit line shielding conductive pattern SL may include forming a bit line shielding conductive film on the bit line shielding insulating liner 171 to fill the bit line shielding region, and recessing an upper surface of the bit line shielding conductive film.

According to embodiments, while the bit line shielding conductive pattern SL is formed, the connection portion SLc of the bit line shielding conductive pattern may be disposed in the peripheral circuit region PCR.

Subsequently, the bit line shielding insulating capping film 175 may be formed on the bit line shielding conductive pattern SL.

Additionally, the bit line shielding insulating capping film 175 may cover the connection portion SLc of the bit line shielding conductive pattern in the peripheral circuit region PCR.

Forming the bit line shielding insulating capping film 175 may include forming a bit line shielding capping insulating film that fills the bit line shielding region where the bit line shielding conductive pattern SL is formed. In addition, forming the bit line shielding insulating capping film 175 may include performing a planarization process on the bit line shielding capping insulating film and the bit line shielding insulating liner 171 to expose upper surfaces of the bit lines BL that are an upper surface of the bit line mask pattern 165.

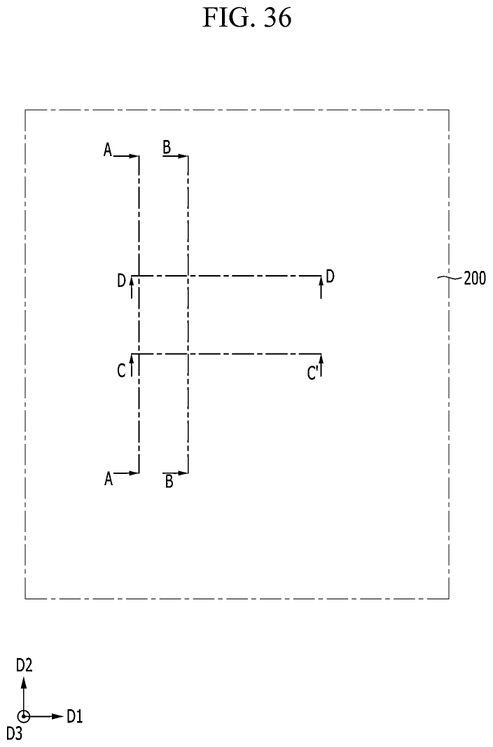

Although not shown in the drawings, the bonding insulating film 263 of FIGS. 36 to 38 described below may be further formed on the bit line shielding insulating capping film 175, the bit line shielding insulating liner 171, and the bit line BL.

Referring to FIGS. 36 to 38, the sub-substrate 200 where the back gate electrode BG, the first and second word lines WL1 and WL2, the first and second active patterns AP1 and AP2, and the bit lines BL may be bonded to the substrate 100 where the peripheral gate structure PG is formed.

The substrate 100 and the sub-substrate 200 may be bonded using the bonding insulating film 263.

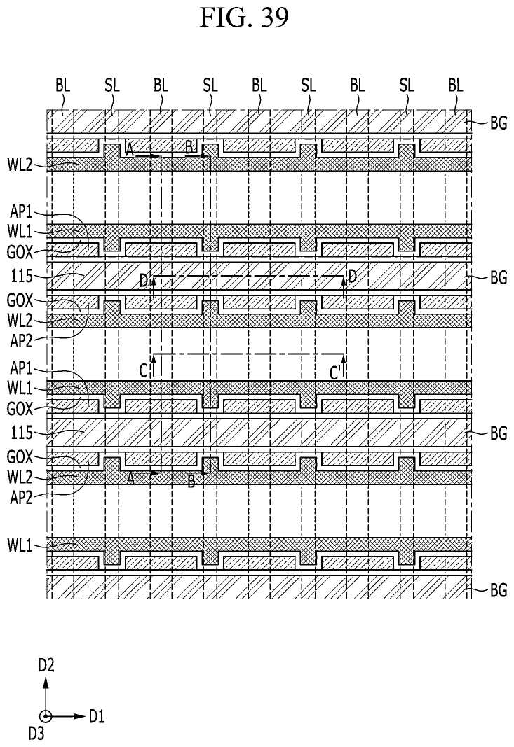

Referring to FIGS. 39 to 42, the first active pattern AP1 and the second active pattern AP2 may be exposed by removing the buried insulating layer 201.

First, after the substrate 100 and the sub-substrate 200 are bonded, a rear surface lapping process removing the sub-substrate 200 may be performed.

Removing the sub-substrate 200 may include sequentially performing a grinding process and a wet etching process to expose the buried insulating layer 201.

Subsequently, the first active pattern AP1 and the second active pattern AP2 may be exposed by removing the buried insulating layer 201. In this case, the buried insulating layer 201 may be removed so that a portion of the gate insulating pattern GOX and a portion of the back-gate insulating pattern 113 are exposed.

Subsequently, the exposed gate insulating pattern GOX and the exposed back-gate insulating pattern 113 may be removed. Through this, the back gate electrode BG, the first word line WL1, and the second word line WL2 may be exposed.

Subsequently, a portion of each of the back gate electrode BG, a portion of the first word line WL1, and a portion of the second word line WL2 may be removed by performing an etch-back process.

Subsequently, the back-gate separation pattern 111 may be formed on a recessed back gate electrode BG. Additionally, the gate capping pattern 143 may be formed on recessed first and second word lines WL1 and WL2. The back-gate separation pattern 111 and the gate capping pattern 143 may be simultaneously formed.

Selectively, a portion of an upper end of the gate insulating pattern GOX and a portion of an upper end of the back-gate insulating pattern 113 may be removed. As an example, if the gate insulating pattern GOX and the back-gate insulating pattern 113 include a silicon oxide film, the first active pattern AP1 and the second active pattern AP2 include monocrystalline silicon, and the gate separation pattern 143 and the back-gate separation pattern 111 include a silicon nitride film, only portions of the gate insulating pattern GOX and the back-gate insulating pattern 113 may be selectively removed.

Accordingly, the heights H_GOX and H_113 of the second surfaces of the gate insulating pattern GOX and the back-gate insulating pattern 113 based on the bit line BL may be lower than the height H_AP of each of the first active pattern AP1 and the second active pattern AP2 based on the bit line BL. In addition, the heights H_GOX and H_113 of the second surfaces of the gate insulating pattern GOX and the back-gate insulating pattern 113 based on the bit line BL may be lower than the heights H_143 and H_111 of the second surfaces of the gate separation pattern 143 and the back-gate separation pattern 111 based on the bit line BL.

That is, the first active pattern AP1 and the second active pattern AP2 may protrude above the second surfaces of the gate insulating pattern GOX and the back-gate insulating pattern 113. Accordingly, as described later, it may be easier to form the protruding portion 800 by the selective epitaxial growth (SEG) method using the body portion 850 of each of the first active pattern AP1 and the second active pattern AP2 as a seed. However, the present disclosure is not limited thereto, and even if the first active pattern AP1 and the second active pattern AP2 protrude above the second surfaces of the gate insulating pattern GOX and the back-gate insulating pattern 113 as the portion of the upper end of the gate insulating pattern GOX and the portion of the upper end of the back-gate insulating pattern 113 are not removed, it is possible to form the protruding portion 800 by the selective epitaxial growth (SEG) method using the body portion 850 of each of the first active pattern AP1 and the second active pattern AP2 as the seed.

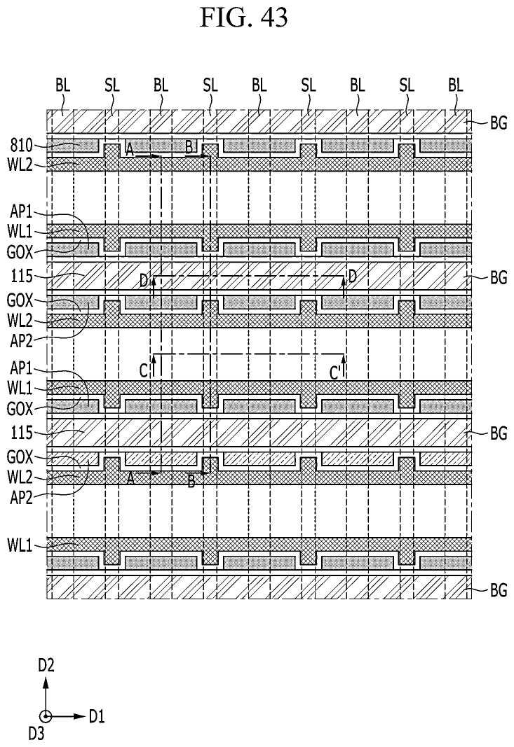

Referring to FIGS. 43 to 46, a selective epitaxial growth is performed using a source gas of a semiconductor material that does not include an impurity gas to form the central portion 810 of the protrusion portion 800.

For example, in the selective epitaxial growth (SEG) method, one period including a process in which the substrate 100 where the body portion 850 of each of the first active pattern AP1 and the second active pattern AP2 is exposed by the gate separation pattern 143 and the back-gate separation pattern 111 is loaded into a chamber and then a source gas, an etching gas, and a reduction gas are sequentially implanted into the chamber, may be repeatedly performed at least twice.

The inside of the chamber where the substrate 100 is loaded is adjusted to a pressure lower than an atmospheric pressure using a vacuum pump or the like, and the substrate 100 is heated to a predetermined temperature. After the substrate 100 is heated, the source gas is implanted into the chamber. Here, the source gas may include a source gas (for example, a silicon source gas, a germanium source gas, or a combination thereof) for forming the protruding portion 800. The source gas is decomposed by a thermal energy to generate a silicon nucleus, a germanium nucleus, or a silicon-germanium (Si—Ge) nucleus. Accordingly, the silicon nucleus, the germanium nucleus, or the silicon germanium-nucleus combines with a dangling bond on a surface of the substrate 100 to be adsorbed to a front surface of the substrate 100. As a result, a semiconductor layer is formed on the front surface of the substrate 100.

After the semiconductor layer is formed, implantation of the source gas is blocked, and the etching gas (for example, a chlorine (Cl₂) gas) is implanted into the chamber. The etching gas combines with atoms of the semiconductor layer formed on surfaces of the gate separation pattern 143 and the back-gate separation pattern 111 to be exhausted to the outside of the chamber. Accordingly, the semiconductor layer formed on the surfaces of the gate separation pattern 143 and the back-gate separation pattern 111 is selectively removed. In contrast, the semiconductor layer formed on a surface of the exposed body portion 850 still remains. This is because an adsorption coefficient on the surfaces of the gate separation pattern 143 and the back-gate separation pattern 111 is different from an adsorption coefficient on the surface of the exposed body portion 850. On the other hand, while the etching gas is implanted, a surface of the semiconductor layer remaining on the exposed body portion 850 may be passivated by the etching gas. In other words, atoms of the etching gas may combine with the atoms of the semiconductor layer.

After implantation of the etching gas is blocked, the reduction gas (for example, a hydrogen gas) is implanted into the chamber. Accordingly, the atoms of the etching gas adsorbed on the surface of the semiconductor layer react with the reduction gas to be removed. As a result, a new semiconductor layer may be easily grown on the semiconductor layer during implantation of a subsequent source gas.

Selectively, while at least one of a process of implanting the source gas, a process of implanting the etching gas, and a process of implanting the reduction gas is performed, an impurity gas may be additionally implanted. Accordingly, a desired concentration of the impurity may be easily adjusted each period, and the protruding portion 800 may have the central portion 810 doped with the impurity, or the protruding portion 800 may have a surface layer portion 820 doped with the impurity. For example, if phosphorus (P) is used as an n-type impurity, phosphorus (P), phosphine (PH₃), or the like may be used as the impurity gas, and if boron (B) is used as a p-type impurity, boron (B), boron difluoride (BF₂), boron trifluoride (BF₃), or the like may be used as the impurity gas.

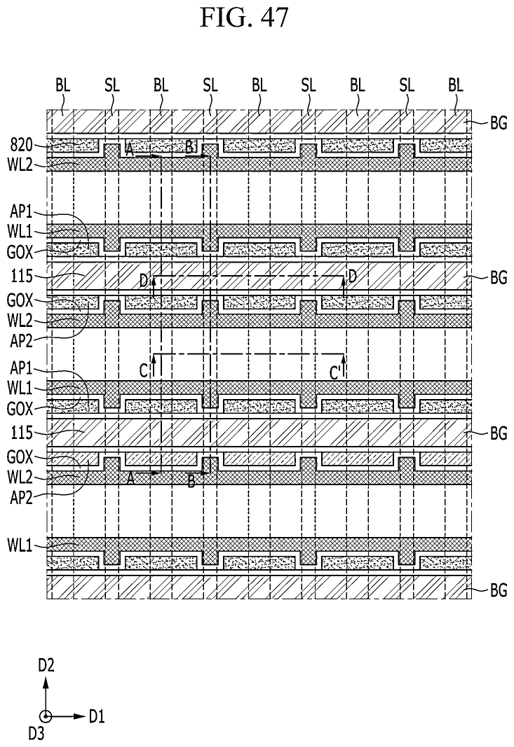

Referring to FIGS. 47 to 50, the surface layer portion 820 surrounding a surface of the central portion 810 of the protruding portion 800 is formed.

As an example, the central portion 810 may be formed by performing a first selective epitaxial growth using a source gas of a semiconductor material that does not include an impurity gas, and then the surface layer portion 820 may be formed by performing a second selective epitaxial growth on a surface of the central portion 810 using a source gas of a semiconductor material that includes an impurity gas and annealing the grown epitaxial.

Alternatively, the central portion 810 may be formed by performing a first selective epitaxial growth using a source gas of a semiconductor material that does not include an impurity gas, and then the surface layer portion 820 may be formed by doping an impurity in the central portion 810 using gas phase diffusion (GPD) or ion implantation.

Accordingly, the central portion 810 of the protruding portion 800 may include a monocrystalline semiconductor material in which an impurity is not doped, and the surface layer portion 820 may include a monocrystalline semiconductor material in which an impurity is doped.

Next, the second dopant region SDR2 is formed at an upper end of the body portion 850.

As an example, in a process in which the central portion 810 is formed by performing a first selective epitaxial growth using a source gas of a semiconductor material that does not include an impurity gas and then the surface layer portion 820 is formed by performing a second selective epitaxial growth on a surface of the central portion 810 using a source gas of a semiconductor material that includes an impurity gas and annealing the grown epitaxial, an impurity may be doped to an upper end of the body portion 850 through the annealing to form the second dopant region SDR2 of the body portion 850.

Alternatively, in a process in which the central portion 810 is formed by performing a first selective epitaxial growth using a source gas of a semiconductor material that does not include an impurity gas and then the surface layer portion 820 is formed by doping an impurity in the central portion 810 using gas phase diffusion (GPD) or ion implantation, the impurity may be doped to an upper end of the body portion 850 to form the second dopant region SDR2.

Accordingly, the second dopant region SDR2 of the body portion 850 may be connected to the surface layer portion 820 of the protruding portion 800 including a monocrystalline semiconductor material doped with an impurity.

However, the central portion 810 may be formed by performing a first selective epitaxial growth using a source gas of a semiconductor material that does not include an impurity gas, and then the second dopant region SDR2 may be formed by doping an impurity in an upper end of the body portion 850 using gas phase diffusion (GPD) or ion implantation.

In this case, the protruding portion 800 of each of the first active pattern AP1 and the second active pattern AP2 may not include the surface layer portion 820, and the second dopant region SDR2 of the body portion 850 may be connected to the central portion 810 of the protruding portion 800.

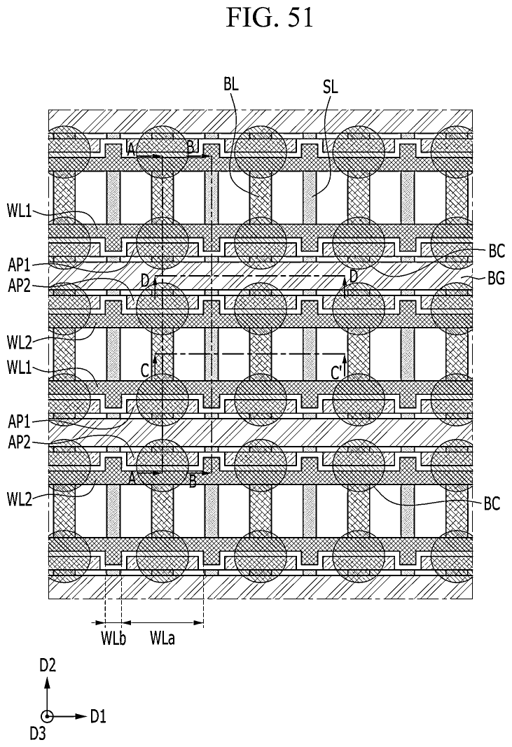

Referring to FIGS. 51 to 54, the contact pattern BC is formed on the first active pattern and the second active pattern. The contact patterns BC may be connected to the first active pattern AP1 and the second active pattern AP2.

As an example, the contact pattern BC may be formed in an engraved manner. That is, after the contact etching stop films 211 and 212 and the contact interlayer insulating film 231 are sequentially formed and a contact hole penetrating the sequentially formed films is formed, the contact pattern BC may be formed within the contact hole.

Alternatively, the contact pattern BC may be formed in an embossed manner. That is, a contact film that contacts the first active pattern AP1 and the second active pattern AP2 may be formed on the front surface of the substrate 100, and the contact film may be patterned to form the contact pattern BC. A contact separation pattern (not shown) may be formed between the contact patterns BC spaced apart from each other.

On the other hand, in a process of forming the contact pattern BC, the interface layer 830 including metal silicide may be formed between the central portion 810 or the surface layer portion 820 of the protruding portion 800 and the contact pattern BC. That is, the interface layer 830 may be formed between the central portion 810 or the surface layer portion 820 of the protruding portion 800 and the contact pattern BC.

Subsequently, the data storage patterns DSP may be formed on the contact patterns BC.

Additionally, a lower peripheral contact plug hole may be formed in the peripheral circuit region PCR. The lower peripheral contact plug hole may expose the metal pattern 163 disposed at an end portion of the bit line BL, the connection portion SLc of the bit line shielding conductive pattern SL, and the peri wiring line 241a. The lower peripheral contact plug hole may be formed through the element separation film STI. The lower peripheral contact plugs LPLGa, LPLGb, and LPLGc may be formed within the lower peripheral contact plug hole.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

100: substrate
PG: peripheral gate structure
AP1, AP2: first active pattern, second active pattern
BL: bit line
WL1, WL2: first word line, second word line
BG: back gate electrode
BC: contact pattern
LP: landing pad
DSP: data storage pattern
800: protruding portion
810: central portion
820: surface layer portion
830: interface layer
850: body portion

What is claimed is:

1. A semiconductor memory device, comprising:
a substrate;
bit lines above the substrate and spaced apart from each other in a first direction, the bit lines extending in a second direction, the second direction being different from the first direction;
a first active pattern and a second active pattern on the bit lines and spaced apart from each other in the second direction; and
a first word line and a second word line between the first active pattern and the second active pattern, the first word line being adjacent to the first active pattern and the second word line being adjacent to the second active pattern, wherein
the first active pattern, the second active pattern, or both the first active pattern and the second active pattern include a body portion and a protruding portion,
the body portion extends in a third direction,
the protruding portion protrudes from an upper end of the body portion in the third direction and has a width in the second direction that is greater than a width of the body portion in the second direction, and
the third direction is different from the first direction and the second direction.

2. The semiconductor memory device of claim 1, wherein
the protruding portion comprises a central portion and a surface layer portion surrounding the central portion,
the central portion includes a monocrystalline semiconductor material that is not doped with an impurity, and
the surface layer portion includes a monocrystalline semiconductor material doped with an impurity.

3. The semiconductor memory device of claim 2, wherein
the protruding portion further includes an interface layer surrounding the surface layer portion and the interface layer includes a metal silicide.

4. The semiconductor memory device of claim 2, wherein
the body portion has a dopant region, and
the dopant region is doped with an impurity at the upper end of the body portion in the third direction.

5. The semiconductor memory device of claim 4, wherein
the dopant region of the body portion is connected to a surface layer including a monocrystalline semiconductor material with an impurity of the protruding portion.

6. The semiconductor memory device of claim 1, wherein
the protruding portion comprises a central portion and an interface layer surrounding the central portion,
the central portion includes a monocrystalline semiconductor material doped with an impurity, and
the interface layer includes metal silicide.

7. The semiconductor memory device of claim 1, wherein
on a cross-section cut in the second direction and the third direction at a midpoint in the first direction of at least one of the first active pattern or the second active pattern, the protruding portion has a circular shape, an oval shape, a triangular shape, a quadrangular shape, a pentagonal shape, a hexagonal shape, a rhombic shape, or a trapezoidal shape.

8. The semiconductor memory device of claim 1, further comprising:
a contact pattern on the first active pattern and the second active pattern, wherein
the contact pattern is connected to the first active pattern and the second active pattern.

9. The semiconductor memory device of claim 8, wherein
at least a portion of the protruding portion is in the contact pattern, and
the contact pattern surrounds at least a portion of the protruding portion.

10. The semiconductor memory device of claim 8, wherein
the protruding portion includes a central portion, a surface layer portion surrounding the central portion, and an interface layer surrounding the surface layer portion,
the central portion includes a monocrystalline semiconductor material that is not doped with an impurity,
the surface layer portion includes a monocrystalline semiconductor material doped with an impurity,
the interface layer includes metal silicide, and
the interface layer is between the surface layer portion and the contact pattern.

11. The semiconductor memory device of claim 8, further comprising:
a back gate electrode on the substrate, wherein at least one of
the first active pattern is between the back gate electrode and the first word line, or
the second active pattern is between the back gate electrode and the second word line.

12. The semiconductor memory device of claim 11, further comprising:
a gate insulating pattern between the first word line and the first active pattern and between the second word line and the second active pattern; and
a back-gate insulating pattern between the back gate electrode and the first active pattern and between the back gate electrode and the second active pattern, wherein
in each of the first active pattern and the second active pattern, a height of an upper end of the protruding portion in the third direction with respect to an underlying one of the bit lines is higher than a height of an upper end of the gate insulating pattern in the third direction and a height of an upper end of the back-gate insulating pattern in the third direction.

13. The semiconductor memory device of claim 12, further comprising:
a back-gate separation pattern on the back gate electrode and between the first active pattern and the second active pattern; and
a gate separation pattern between the first word line and the contact pattern and between the second word line and the contact pattern, wherein
in each of the first active pattern and the second active pattern, the height of the upper end of the protruding portion in the third direction over the underlying one of the bit lines is higher than a height of an upper end of the gate separation pattern in the third direction and higher than a height of an upper end of the back-gate separation pattern in the third direction.

14. The semiconductor memory device of claim 13, wherein
the height of the upper end of the gate separation pattern and the height of the upper end of the back-gate separation pattern are higher in the third direction with respect to the underlying one of the bit lines than the height of the upper end of the gate insulating pattern in the third direction and the height of the upper end of the back-gate insulating pattern in the third direction.

15. The semiconductor memory device of claim 1, further comprising:
a contact pattern on the first active pattern and the second active pattern, the contact pattern being connected to the first active pattern and the second active pattern; and
a gate separation pattern between the first word line and the contact pattern and between the second word line and the contact pattern; and
a back-gate separation pattern between the first active pattern or the second active pattern, wherein
the contact pattern comprises a first extension portion and a second extension portion,
the first extension portion protrudes between the gate separation pattern and the first active pattern or the second active pattern, and
the second extension portion protrudes between the back-gate separation pattern and the first active pattern or the second active pattern.

16. The semiconductor memory device of claim 15, wherein the protruding portion is between the first extension portion of the contact pattern and the second extension portion of the contact pattern.

17. The semiconductor memory device of claim 1, further comprising:
a shielding structure adjacent to one of the bit lines, wherein
the shielding structure is above the substrate and extends in the second direction.

18. The semiconductor memory device of claim 1, further comprising:
a peripheral gate structure between the substrate and at least one of the bit lines; and
a bonding insulating film between the peripheral gate structure and the bit line.

19. A semiconductor memory device, comprising:
a substrate;
bit lines above the substrate and spaced apart from each other in a first direction, the bit lines extending in a second direction, the second direction being different from the first direction;
a first active pattern and a second active pattern on the bit lines and spaced apart from each other in the second direction; and
a first word line and a second word line between the first active pattern and the second active pattern, the first word line being adjacent to the first active pattern and the second word line being adjacent to the second active pattern, wherein
the first active pattern, the second active pattern, or both the first active pattern and the second active pattern include a body portion and a protruding portion,
the body portion extends in a third direction,
the protruding portion protrudes from an upper end of the body portion in the third direction,
the protruding portion includes a central portion and a surface layer portion surrounding the central portion,
the central portion includes a monocrystalline semiconductor material that is not doped with an impurity, and
the surface layer portion includes a monocrystalline semiconductor material that is doped with an impurity.

20. A semiconductor memory device, comprising:
a substrate;
bit lines above the substrate and spaced apart from each other in a first direction, the bit lines extending in a second direction, the second direction being different from the first direction;
a first active pattern and a second active pattern on the bit lines and spaced apart from each other in the second direction;
a first word line and a second word line between the first active pattern and the second active pattern, the first word line being adjacent to the first active pattern and the second word line being adjacent to the second active pattern;
a first back gate electrode facing the first word line with the first active pattern between the first word line and the first back gate electrode; and
a second back gate electrode facing the second word line with the second active pattern between the second word line and the second back gate electrode, wherein
the first active pattern, the second active pattern, or both the first active pattern and the second active pattern include a body portion and a protruding portion,
the body portion extends in a third direction,
the protruding portion protrudes from an upper end of the body portion in the third direction and has a width along the second direction that is greater than a width of the body portion,
the protruding portion includes a central portion and a surface layer portion surrounding the central portion,
the central portion includes a monocrystalline semiconductor material that is not doped with an impurity, and
the surface layer portion includes a monocrystalline semiconductor material doped with an impurity.
